(19) United States
(12) Patent Application Publication
(10) Pub. No.: US 2017/0207600 A1
(43) Pub. Date: Jul. 20, 2017

(54) 3D PHOTONIC INTEGRATION WITH LIGHT COUPLING ELEMENTS

(71) Applicant: Biond Photonics Inc., Oceanside, NY (US)

(72) Inventors: Jonathan Klamkin, Oceanside, NY (US); Sasa Ristic, Montreal (CA)

(73) Assignee: Biond Photonics Inc., Oceanside, NY (US)

(21) Appl. No.: 15/326,452

(22) PCT Filed: Jul. 14, 2015
(86) PCT No.: PCT/US15/40344

§ 371 Date: Jan. 13, 2017

Related U.S. Application Data
(60) Provisional application No. 62/024,379, filed on Jul. 14, 2014.

(51) Int. Cl. H01S 5/022; H01S 5/14; G02B 6/14; H01S 5/026; G02B 6/13; G02B 6/12

(52) U.S. Cl. CPC H01S 5/0224; G02B 6/13; G02B 6/12004; G02B 6/14; H01S 5/026; H01S 5/142; H01S 5/02292; G02B 2006/12104; G02B 6/124

(57) ABSTRACT

Methods for realizing integrated lasers and photonic integrated circuits on complimentary metal-oxide semiconductor (CMOS)-compatible silicon (Si) photonic chips, potentially containing integrated electronics, are disclosed. The integration techniques rely on light coupling with integrated light coupling elements such as turning mirrors, lenses, and surface grating couplers. Light is coupled from between two or more substrates using the light coupling elements. The technique can realize integrated lasers on Si where a gain flip chip (the second substrate) is bonded to a Si chip (the first substrate) and light is coupled between a waveguide in the gain flip chip to a Si waveguide by way of a turning mirror or grating coupler in the flip chip and a grating coupler in the Si chip. Integrated lenses and other elements such as spot-size converters can also be incorporated to alter the mode from the gain flip chip to enhance the coupling efficiency to the Si chip. The light coupling integration technique also allows for the integration of other components such as modulators, amplifiers, and photodetectors. These components can be waveguide-based or non-waveguide based, that is to say, surface emitting or illuminating.

### CROSS REFERENCE TO RELATED APPLICATION

This claims the benefit of U.S. Provisional Application No. 62/024,379, filed Jul. 14, 2014, which is incorporated by reference herein.

### FIELD OF THE DISCLOSURE

The present invention is directed to semiconductor optoelectronic devices, and, more specifically, to the integration of different optoelectronic devices through light coupling elements such as turning mirrors, lenses, and gratings.

### BACKGROUND

Silicon (Si) photonics has emerged as an effective photonic integration platform for realizing high-functionality photonic integrated circuits (PICs) that comprise more than one photonic function on a chip. This technology platform can realize compact transmitters and receivers for optical communication and sensing applications. Passive components such as, but not limited to, optical splitters, combiners, arrayed waveguide gratings (AWGs), and echelle gratings, can be fabricated in Si with excellent performance and small size. Some active components have also been demonstrated in Si including optical modulators based on P-N junctions and photodiodes (PDs) based on germanium (Ge) on Si (Ge/Si) or ion implantation. Although the performance of these components is reasonable, for some applications it would be beneficial to have higher performance afforded by other material systems such as, but not limited to, lithium niobate (LiNbO₃), indium phosphide (InP), or gallium arsenide (GaAs).

Realizing laser sources on Si is extremely challenging because Si has an indirect bandgap and therefore it is not efficient for light emission. Direct bandgap group III-V semiconductors such as InP or GaAs, on the other hand, make for efficient light emitters. One solution is to simply co-package a laser fabricated from a III-V material, such as InP, that emits light at typical optical communication wavelengths, and couple the light from the laser chip to the Si using microoptics. This is a fairly cumbersome approach that requires several microoptics components including a lens and an optical isolator. This approach also does not scale well for applications that require more than one laser source.

On-chip integration approaches have been proposed such as integration of an InP laser chip directly on the Si chip. In this case the laser chip can be attached to the Si chip by flip-chip bonding and the light is butt-coupled from the InP planar waveguide to the Si planar waveguide. This approach requires both horizontal and vertical alignment and typically requires active alignment, meaning the alignment tolerance is low and therefore some active monitoring is required during the chip attachment.

Another approach relies on wafer bonding of InP to Si and then the subsequent removal of the InP substrate and post-bonding fabrication of the InP chip. The light generated in the InP gain medium, which is positioned directly above a Si waveguide, evanescently couples to the Si waveguide. This approach relies on an extremely sensitive wafer bonding step, which poses yield issues. It also requires processing incompatible materials and exhibits inherent reliability issues because the two materials have significantly different coefficients of thermal expansion, and these materials are brought into intimate contact through wafer bonding. Although the wafer bonding approach allows for scalability (i.e. increasing number of lasers on a Si chip), to be executed effectively, it requires fabrication of both the InP and Si materials in the same facility. These are incompatible materials and therefore significant investments are required to mature the technology.

### SUMMARY

The present invention provides a technology for realizing highly manufacturable and scalable photonic integrated circuits (PICs) on Si and other substrates. By flip-chip or direct bonding photonic chips, light can be coupled to and from these photonic chips using turning mirrors, lenses, and surface grating couplers. These light coupling elements could also be used for coupling light between layers in a single chip or between the topside and backside of a chip. We generally refer to optical coupling between chips as vertical light coupling, although the direction of coupling need not be precisely vertical. As examples, this integration technique allows for the realization of small form factor and high performance lasers on Si, as well as the integration of optical modulators and PDs on Si with higher performance than could be realized directly with Si or Ge/Si. This integration technique could be carried out in a backend step rather than frontend processing, meaning that the Si PIC and the other photonic chips (for example an InP gain chip) are fabricated separately, then joined together in the bonding step. Alternatively, if some co-fabrication is beneficial, for example in allowing for direct alignment of turning mirrors in one chip to grating couplers in a Si chip, this is possible as well.

The approach proposed here, which relies on bonding and vertical light coupling, does not require co-processing of separate chips. There are no restrictions on where the chips are fabricated and they can be simply integrated following their separate and complete fabrication. There are also no restrictions on which photonic components can be integrated. This approach has the scalability and compactness advantages of the wafer-bonding approach and requires only passive alignment in one plane (during the bonding step). It is therefore extremely reliable and manufacturable.

Si devices and PICs utilizing the present invention can take many forms and can be applied to many applications that require one or more of the following components, fabricated in any photonic material (such as, but not limited to, Si, silicon nitride, silica, Ge, InP, GaAs, LiNbO₃): optical amplifier, laser, tunable laser, optical modulator, variable optical attenuator, photodetector, beam splitter, beam combiner, echelle grating, arrayed waveguide grating, multimode interference coupler, polarization splitter, polarization rotator, combined polarization splitter/rotator, Bragg grating reflector, Bragg grating filter, microring resonator. The present invention can be used to integrate any of these components, or an integrated chip containing more than one of those components, onto another substrate, for example a Si substrate, that contains other photonic components such as those listed above.

The base chip, that to which other components would be attached, is referred to as the “first substrate.” A substrate can be either in full wafer form, or a single chip that is a piece separated from a full wafer. The chip to be attached is referred to as the “second substrate.” The second substrate can be attached in any orientation to the first substrate, although most examples herein orient the substrates in parallel. Several substrates can be attached to the first substrate, each utilizing light coupling elements for coupling to the first substrate. Stacking of substrates is also possible, wherein more than two substrates are stacked and light is coupled between adjacent substrates using the light coupling techniques described. Attachment of substrates can also be carried out at the wafer level, meaning that several second substrates can be attached to a first substrate, which is in full wafer form. The vertical light coupling techniques can also be utilized to couple light between layers on a single substrate.

The second substrate could be attached using conventional flip-chip techniques that utilize metals or solders, or could be attached using direct bonding with or without an interfacial layer such as, but not limited to, an oxide or polymer film. Direct bonding employed in the present invention does not require molecular bonding and instead could use an interfacial oxide or polymer layer that renders the bonding more robust and mitigates issues associated with the mismatch of thermal expansion coefficients of the different substrates. This invention does not require co-processing the chips; instead the bonding could occur after the chips have been separately fabricated. The substrates would contain light coupling elements such as turning mirrors, lenses, and grating couplers, or could be inherently surface illuminated or surface emitting (such as, but not limited to, a surface normal PIN PD, surface normal avalanche PD (APD), or surface emitting vertical cavity semiconductor optical amplifier (VCSOA)). Light can be coupled to (from) the first substrate through surface grating couplers that could be designed to match the mode shape of the component to be coupled from (to) on the second substrate. Alternatively to using a turning mirror, the second substrate could employ a surface grating coupler, curved turning mirror, or lens. These elements could serve to alter the mode making it more amenable to coupling to a grating coupler in the first substrate. A spot-size converter could also be incorporated in the second substrate to alter the mode.

In one embodiment, to realize integrated lasers on Si, a gain chip (second substrate) with an integrated turning mirror can be bonded to a Si substrate (first substrate) containing other photonic components, and light from the gain chip can be coupled to a Si waveguide through a surface grating coupler.

In another embodiment, to realize sensitive photodetection on Si, a surface normal APD or PIN PD chip (second substrate) can be bonded to a Si substrate (first substrate) containing other photonic components, and light from the Si substrate can be coupled to the surface normal PD chip through a surface grating coupler formed in the Si waveguide layer.

### BRIEF DESCRIPTION OF THE DRAWINGS

Referring to the drawings which are referenced throughout:

FIG. 1 is a sideview schematic of an integrated laser in accordance with an embodiment of the invention;

FIG. 2 is a topview schematic of a waveguide taper that increases the lateral size of the optical mode of the flip chip;

FIG. 3 is a sideview schematic of an integrated laser with a turning mirror with an angle less than 45° illustrating a light path in accordance with an embodiment of this invention;

FIG. 4 is a sideview schematic of an integrated laser with a turning mirror with an angle greater than 45° illustrating a light path in accordance with an embodiment of this invention;

FIG. 5 is a sideview schematic of an integrated laser incorporating active-passive integration in accordance with an embodiment of this invention;

FIG. 6 is a sideview schematic of an integrated laser where the gain flip chip is bonded on top of the oxide cladding instead of on the Si layer in accordance with an embodiment of this invention;

FIG. 7 is a sideview schematic of an integrated SOA in accordance with an embodiment of this invention;

FIG. 8 is a sideview schematic of an integrated two-mirror DBR laser in accordance with an embodiment of this invention;

FIG. 9 is a topview schematic of a two-port integrated laser realized with ring resonators in accordance with an embodiment of this invention;

FIG. 10 is a topview schematic of a two-port integrated laser where a gain medium waveguide incorporates a 180° turn in accordance with an embodiment of this invention;

FIG. 11 is a cross section schematic of a an integrated laser illustrating a metal contacting scheme in accordance with an embodiment of this invention;

FIG. 12 is a topview schematic of a transmitter with four integrated lasers in accordance with an embodiment of this invention;

FIG. 13 is a cross section schematic of an integrated laser illustrating a modified metal contacting scheme in accordance with an embodiment of this invention;

FIG. 14 is a topview schematic of an apodized/nonuniform grating coupler in accordance with an embodiment of this invention;

FIG. 15 is a sideview schematic of an integrated laser where the Si in the grating coupling region is made thicker in accordance with an embodiment of this invention;

FIG. 16 is a sideview schematic of an integrated laser where a grating is incorporated in the gain flip chip in accordance with an embodiment of this invention;

FIG. 17 is a sideview schematic of an integrated laser realized with a bottom emitting gain flip chip in accordance with an embodiment of this invention;

FIG. 18 is a sideview schematic of an integrated laser realized with a bottom emitting gain flip chip that is bonded to the Si with an interfacial layer in accordance with an embodiment of this invention;

FIG. 19 is a sideview schematic of an integrated laser where a grating is incorporated at the chip/air interface of the gain flip chip in accordance with an embodiment of this invention;

FIG. 20 is a sideview schematic of an integrated laser where lenses are utilized to alter the mode in the flip chip in accordance with an embodiment of this invention;

FIG. 21 is a sideview schematic of an integrated laser where the flip chip is attached directly to the Si chip in a recessed opening in the backside of the Si chip;

FIG. 22 is a sideview schematic of an integrated laser where the flip chip is attached by flip-chip bonding to the Si chip in a recessed opening in the backside of the Si chip;

FIG. 23 is a sideview schematic of a PIC where an EML chip is bonded to the Si chip in accordance with an embodiment of this invention;

FIG. 24 is a topview schematic of a PIC where a transceiver is realized in accordance with an embodiment of this invention;

FIG. 25 is a sideview schematic of an integrated surface illuminated photodetector in accordance with an embodiment of this invention;

FIG. 26 is a topview schematic of a PIC transceiver employing a single integrated laser source in accordance with an embodiment of this invention;

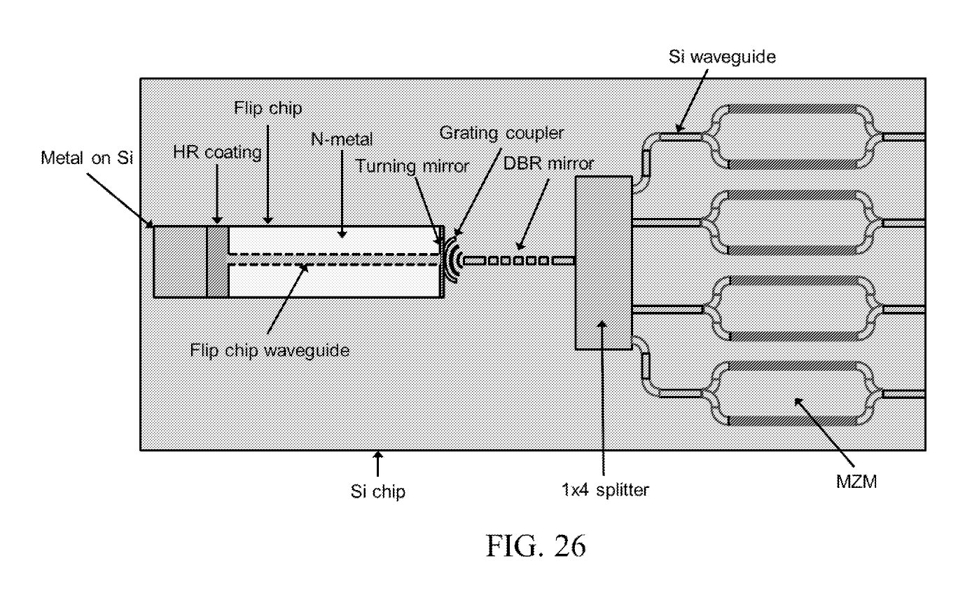

FIG. 27 is a topview schematic of a PIC transceiver employing four integrated laser sources in accordance with an embodiment of this invention;

FIG. 28 is a topview schematic of a PIC transceiver employing four integrated laser sources from two separate flip chips in accordance with an embodiment of this invention;

FIG. 29 is a sideview schematic of an integrated laser where the flip chip is bonded directely to the Si chip in a recessed opening in accordance with an embodiment of the invention;

FIG. 30 is a sideview schematic of an integrated laser where the a reflector layer is incorporated below the Si waveguide in accordance with an embodiment of the invention;

FIG. 31 is a block diagram schematic of a surface emitting photonic device comprising a horizontal (with respect to the plane of the substrate) waveguide, a spot size converter, and a horizontal to out-of-plane transition element, in accordance with an embodiment of the invention;

FIG. 32 is a block diagram schematic of a photonic integrated circuit formed by attaching an out-of-plane illuminating or emitting photonic device to another device comprising a horizontal to out-of-plane transition element, a spot size converter, and a horizontal (with respect to the plane of the substrate) waveguide, in accordance with an embodiment of the invention.

FIG. 33 depicts a flow diagram illustrating the process for integrating photonic devices to form a photonic integrated circuit, in accordance with an embodiment of the invention.

### DETAILED DESCRIPTION

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest,” “best,” “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” “horizontal, “vertical,” “parallel,” “perpendicular,” and the like. These terms are used for convenient description, but do not imply any particular spatial orientation.

In the examples disclosed herein, optical devices such as waveguides, emitters, detectors, and other optical elements are defined in planar substrates that include major surfaces that are separated by distances on the order of 1 μm to 1 mm. Planar waveguides are defined in planes parallel to the major surfaces, and are referred to in some cases as horizontal waveguides for convenient description. Beam propagation can be referred to as horizontal or vertical, or in-plane and out-of-plane as may be convenient. Typically, beams propagating in a plane of a substance in, for example, a planar waveguide, are coupled out of the substrate along an axis that is at angle with respect to the waveguide axis. This out-of-plane axis need not be perpendicular the planar axis but can be at an oblique angle such as between about 45 degrees and 80 degrees with respect to the in-plane axis. As noted above, such axes are referred to as horizontal and vertical, although they are not necessarily perpendicular. Such a designation does not imply any further spatial orientation. In addition, one or more prisms, mirrors, lenses, diffraction gratings, or other optics (referred to herein as beam direction transitions) is situated so as to couple optical beams into and out of the horizontal waveguide along an axis that is not parallel or co-planar with an axis of a planar waveguide. In some examples, the beam direction transition is situated to direct a beam propagating in or to the planar waveguide along an axis that is out of plane to a substrate major surface so as to couple beams into and out of an optical substrate. As used herein, an axis or a beam axis refers to an optical axis associated with waveguide propagation, or with beam propagation along one or more other directions, within or without a waveguide. In some cases, an axis will be understood to include one or more segments, and an optical axis can be bent, folded, curved or otherwise shaped using one or more prisms, mirrors, diffraction gratings, or other optics which may or may not be integrated into a substrate. For convenience, propagating optical radiation can be referred to as a beam or an optical beam.

The present invention can realize PICs by stacking chips and vertically coupling light between those chips. “Vertical” is used to describe light coupling between adjoining chips, but does not necessarily imply precisely normal to the surface. The chips need not be oriented in parallel, however, for convenience, examples herein orient chips in parallel. Although examples describe the integration of two substrates, the vertical light coupling can be applied to a stacking of more than two chips or substrates. The vertical light coupling between separate chips can also be applied to coupling between layers realized in a single chip.

For many examples that follow, the first substrate is a Si chip and the second substrate is called a flip chip. The present invention, however, applies to any type of substrates and the Si chip and flip chip are used only as examples. The term flip chip also does not necessarily imply that the chip is flipped or that flip-chip bonding is utilized.

As an example, an integrated external cavity laser source on Si could be realized, where gain is provided by a group III-V waveguide gain chip that is bonded to a Si on insulator (SOI) chip comprising an integrated waveguide filter. In one embodiment, a III-V chip, comprising quantum wells (QWs) or quantum dots (QDs), is fabricated as a reflective semiconductor optical amplifier (SOA) where a back facet provides a broadband reflection. The other end of the waveguide gain chip has an integrated turning mirror that is etched at an angle beyond the critical angle allowing for redirection of the light approximately vertically. The angle of the turning mirror would be different than 45° so that the light generated in the III-V gain medium planar waveguide is redirected at an angle off normal to the substrate. The motivation for off-normal redirection of the light is twofold; to optimize coupling of the light to the Si waveguide in the SOI chip through a grating coupler, and to reduce reflection of light back into the gain medium waveguide.

A highly reflective (HR) coating can be applied to the back facet of the reflective SOA chip to increase the optical power coupled to the Si PIC. The integrated waveguide filter in the Si waveguide can be realized by any of a number of elements, including, but not limited to, a distributed Bragg reflector (DBR), a microring resonator or a series of microring resonators, an AWG, or an echelle grating.

To form the laser cavity, one reflector is provided by the back facet of the reflective SOA. A DBR acts as both a filter and reflector, therefore providing the second reflector for the laser cavity. If a microring resonator, AWG, or echelle grating is used for the narrowband filter, a second reflector can be provided by a DBR or a facet in the Si waveguide.

In addition to realizing integrated lasers on Si, photonic integration using vertical light coupling can also be used to realize SOAs, which could be used, for example, to overcome waveguide losses in a PIC or to pre-amplify an optical signal for a receiver. The technique could also realize hybrid-integrated optical modulators and photodetectors. Regarding the latter embodiments, a modulator based on, but not limited to, Si, III-V, or LiNbO₃ could incorporate integrated turning mirrors, grating couplers, or lenses, and can be attached to a Si PIC; light would then be coupled to and from the optical modulator structure using a combination of grating couplers formed in the Si and the vertical light coupling elements formed in the optical modulator structures. Other integrated optics components could also be incorporated, either on the first substrate or the second substrate, to increase the coupling efficiency. Such components could include lenses, graded index (GRIN) elements, plasmonic structures, or metallic or dielectric reflectors.

Light can be coupled through a grating coupler to a surface normal PD such as a PIN-PD or APD that is bonded above a grating coupler. The latter is beneficial for improving the signal-to-noise ratio (SNR) of an eventual optical communications link since APDs are more sensitive than conventional PIN photodetectors. Although the integration technique for realizing lasers is emphasized, many of the technical concepts, such as maximizing of coupling efficiency and grating coupler design, apply to the integration of optical modulators, photodetectors, and other components as well.

In the following, references are made to the accompanying drawings, and as such several embodiments of the present invention are described. It is understood that several other embodiments can be realized and structural changes can be made without departing from the scope of the present invention, which involves photonic integration using light coupling elements such as integrated turning mirrors, lenses, and grating couplers, and mode altering components such as spot-size converters and gratings.

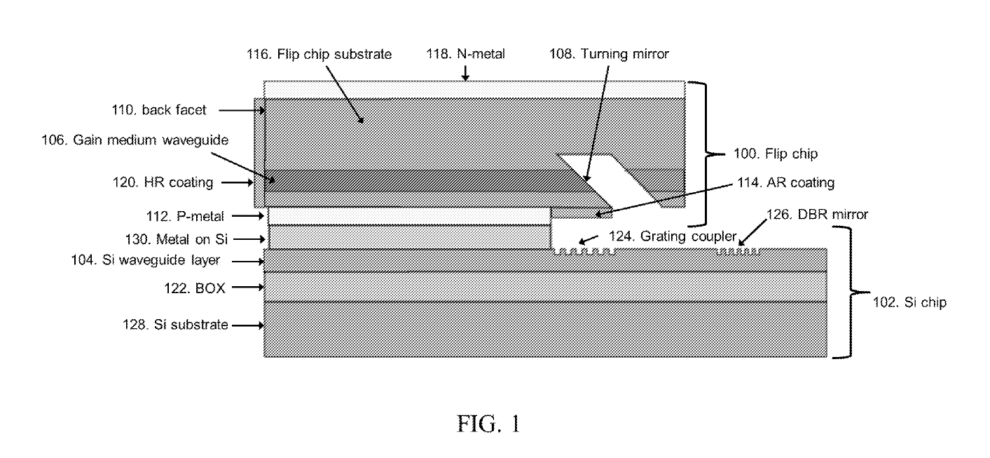

FIG. 1 is a sideview schematic of an example of an integrated laser realized using the present invention. In this embodiment, a second substrate (based on for example, a III-V material, such as, but not limited to, InP or GaAs) and labeled as flip chip, element 100, is fabricated as a reflective SOA. This component could have an HR-coated back facet on one end, and a near-45° turning mirror on the other end. This component could be bonded to a first substrate, for example a Si PIC chip, which is element 102. A number of bonding techniques can be utilized, including, but not limited to, metal-to-metal thermocompression bonding (as illustrated in FIG. 1), solder bonding, direct bonding (with or without an interfacial layer), or adhesive bonding. The embodiment illustrated in FIG. 1 comprises the second substrate (a flip chip in this case), element 100 that is flip-chip-bonded to a waveguide layer, element 104, of the first substrate (a SOI chip in this case), which is element 102. The flip chip and Si chip are fabricated in separate frontend processes and then integrated in a backend flip-chip bonding step. This avoids process incompatibility issues. The sequence of steps to complete the realization of such an integrated laser can be carried out in a number of ways and in different order, and the design of each of the components could be varied, without departing from the scope of the invention.

A planar waveguide geometry can be formed in the flip chip using any form of waveguide configuration such as, but not limited to, a ridge, rib, buried rib or stripe. The waveguide layer, 106, contains an active medium for providing gain. Such an active medium can therefore be denoted a gain medium. The gain can be provided by, but is not limited to, bulk, quantum well (QW), quantum wire, quantum dash, or quantum dot (QD) structures. The gain medium could use materials for the active region such as, but not limited to, indium gallium arsenide (InGaAs), indium gallium arsenide phosphide (InGaAsP), indium aluminum gallium arsenide (InAlGaAs), indium arsenide (InAs), InP, GaAs, aluminum gallium arsenide (AlGaAs), indium gallium arsenide nitride (InGaAsN), indium gallium phosphide (InGaP), indium aluminum arsenide (InAlAs), indium antimonide (InSb), aluminum antimonide (AlSb), aluminum arsenide antimonide (AlAsSb), indium gallium antimonide (InGaSb), indium gallium aluminum antimonide (InGaAlSb), or many combinations therein.

After formation of the 2D planar waveguide, the remaining fabrication of the flip chip can be carried out in a number of ways, some of which are detailed in the following. The turning mirror, 108, can be formed by so called dry etching (such as reactive ion etching (RIE), inductively coupled plasma RIE (ICP-RIE), chemical ion beam etching (CIBE), or chemically-assisted ion beam etching (CAIBE)). The back vertical facet, 110, can be formed by dry etching or in a later step by mechanical cleaving. This configuration is shown in FIG. 1. The dry-etching process for the formation of the angled turning mirror would be carried out in such a way that the substrate is positioned at an angle in comparison to its ordinary configuration. Alternatively, the turning mirror could be formed using a focused ion beam (FIB) process. With this technique, it is possible to carry out the turning mirror formation after all of the frontend processing steps and there is potential to realize an atomically smooth surface. Angled polishing could also be utilized to form the turning mirror, which would be particularly desirable if the flip chip is fabricated from LiNbO₃. Wet etching could also be used as an alternative to form a turning mirror or to polish the surface of the turning mirror.

Referring to a process using dry etching, following formation of the turning mirror (and the back facet if also formed using etching), topside p-metal contacts can be formed, represented by layer 112. A topside anti-reflection (AR) coating, 114, could be applied to the exit surface of the flip chip. The flip chip substrate, 116, could then be thinned and polished, and backside n-metal contacts, 118, could be deposited and annealed. Bars could be formed using mechanical cleaving, and in the case of cleaved back facets as represented in FIG. 1, the back facets could be formed in this cleaving step. A high-reflectivity (HR) coating, 120, could be applied to the back facet of the bars, and finally chips could be separated in a second mechanical cleaving step.

At this point, the flip chip, represented by element 100, could be ready for the flip-chip bonding step. If solder bonding were to be used, separate solder metal layers could have been deposited during the p-metal formation step, or a separate electroplating step could have been carried out to form the solder metals at some point following the p-metal formation step. Alternatively, the solder metals could have been formed on the Si chip. Several chips could be bonded to the Si chips as needed. In addition to chip-to-chip bonding, it is also possible to carry out the bonding at the wafer level; that is to say, chips could be bonded to a full Si wafer prior to dicing the Si wafer.

The Si chip, element 102, shown in FIG. 1, consists of a Si waveguide layer 104, a buried oxide (BOX) layer 122, which is typical Si dioxide (SiO₂), a grating coupler, 124, that is formed in the Si waveguide layer, a DBR mirror, 126, and the Si substrate itself, 128. The Si waveguide structure may contain an upper cladding material, such as SiO₂, however, FIG. 1, and many of the other figures, do not show this layer for simplicity. The Si chip could comprise of many other elements as well, including active components, such as PDs and optical modulators, and passive components, such as splitters and optical filters, however, for simplicity, only those elements required for realizing an integrated laser source, in some specific configuration, are shown in FIG. 1. The lasing wavelength could be tuned by locally heating the DBR mirror, that is to say, by employing the thermooptic effect. It is also be possible alternatively to design the grating coupler as both a coupling element, to couple light from the flip chip to the Si chip, and as a reflector for the laser. Some of the elements and their characteristics, for example the angle of the turning mirror of the flip chip, would be optimized for such a structure.

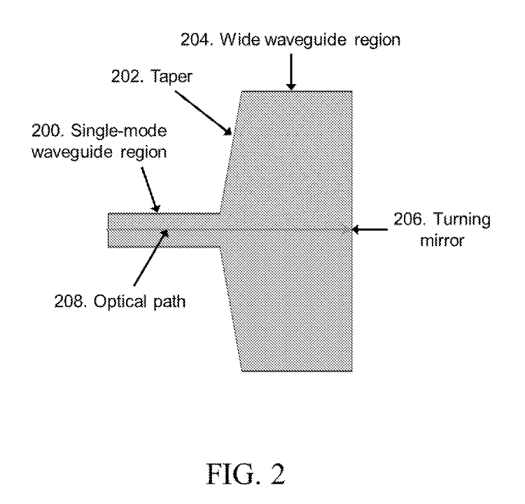

Conventional semiconductor waveguides, such as those used for realizing semiconductor laser and gain chips, emit fairly divergent beams. It is therefore challenging to couple these beams to a Si waveguide through a grating coupler. Several approaches will be described throughout for addressing this issue such as apodized Si grating coupler designs, integrated spot-size converters, and integrated lenses. To reduce the divergence in one dimension, a taper can be incorporated. FIG. 2b shows a topview illustration of an example guiding region of the flip chip with a taper. This taper could be made adiabatic so that light from the single-mode region, element 200, is converted in size but does not excite high-order modes as it propagates through the taper region, element 202, and enters the wide multimode region, element 204. When the light reaches the turning mirror, indicated by element 206, and is redirected vertically, the divergence of the exiting beam will be significantly lower in the transverse dimension. This simplifies the design requirements for the grating coupler and can improve the coupling efficiency and alignment tolerance.

The taper could alternatively be made with a shorter taper length so as not to be adiabatic. Although high-order modes might be excited, the length of the wide waveguide region can be made short so as to minimize any impact on the mode profile. With a non-adiabatic taper the propagating mode will remain roughly localized in the center of the wide waveguide region, minimizing the amount of radiation in the presence of the edge of the waveguide. Upon being redirected from the turning mirror, the light will not overlap with the edges vertically either, minimizing any scattering.

More complex spot-size converters could also be incorporated to minimize the divergence in both dimensions, therefore improving the coupling to the Si chip through the grating coupler. Many types of spot-size converters are available for integration in the flip chip, such as, a spot-size converter that converts from a conventional ridge, rib or buried waveguide to a slab-coupled optical waveguide, which is a thick waveguide structure formed as a rib, whereby single-mode operation is achieved by coupling high-order modes in the ridge region to high-order modes in the slab region. Other types of spot-size converters that could be utilized include, but are not limited to, a lateral down-tapered buried waveguide, a lateral up-tapered buried waveguide, a single lateral taper transition from a ridge waveguide to a grating coupler-matched waveguide, a multi-section taper transition from a ridge waveguide to a grating coupler-matched waveguide, a dual lateral overlapping buried waveguide taper, a dual lateral overlapping ridge waveguide taper, a nested taper transition from a ridge waveguide to a grating coupler-matched waveguide, a vertical down-tapered buried waveguide, a vertical down-tapered ridge waveguide, a vertical overlapping ridge waveguide taper, a vertical overlapping waveguide taper transition from a buried waveguide to a grating coupler-matched waveguide, a vertical overlapping waveguide taper transition from a ridge waveguide to a grating coupler-matched waveguide, a combined lateral and vertical ridge waveguide taper, a 2-D overlapping waveguide transition from a buried waveguide to a grating coupler-matched waveguide, an overlapping waveguide taper transition with two sections from a ridge waveguide to a grating coupler-matched waveguide.

Other elements could also be incorporated to alter the mode size, shape, and divergence angles, such as, but not limited to, gratings incorporated in the flip-chip waveguide, GRIN structures, and lenses.

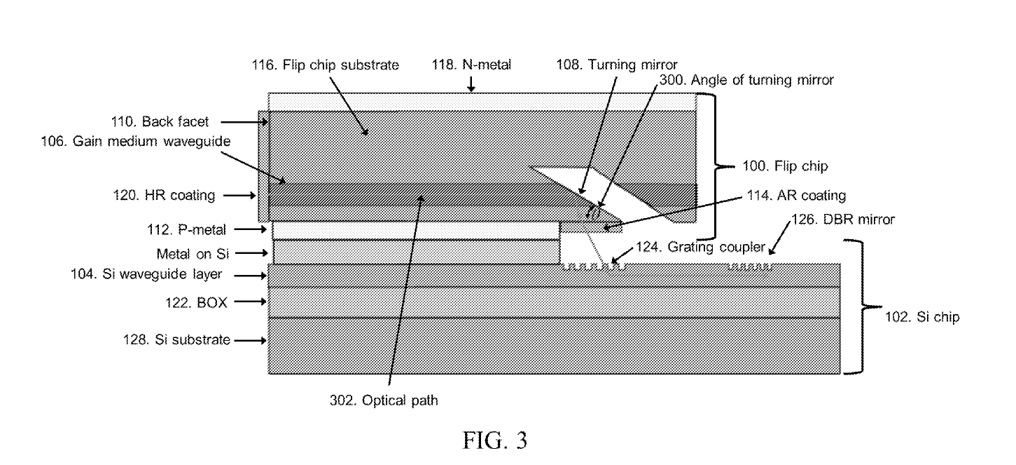

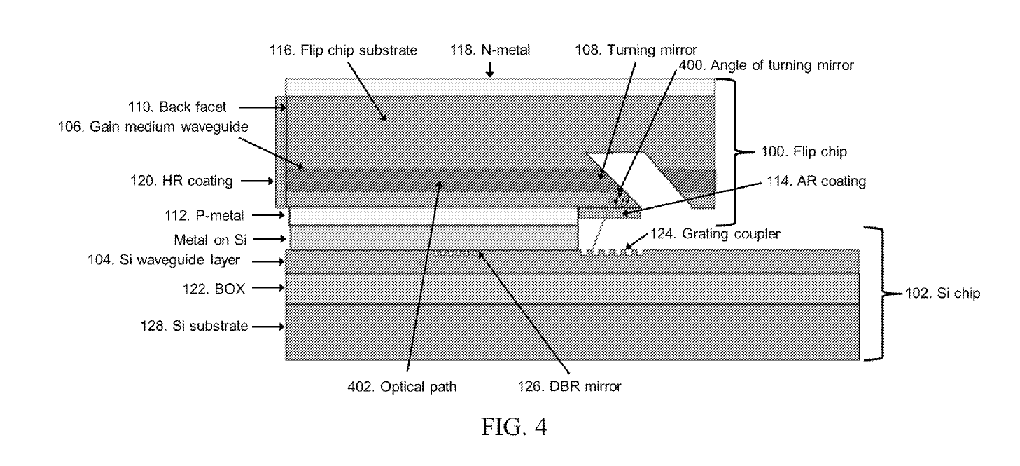

FIG. 3 represents an alternative embodiment, showing a sideview schematic of the integrated laser where the turning mirror formed in the flip chip, 100, is oriented at an angle, represented by element 300, of slightly less than 45° so that the light exits the surface of the flip chip and refracts in the direction away from the flip chip. The approximate light path, 302, is shown. Instead in FIG. 4, a sideview schematic is shown where the turning mirror in the flip chip is oriented at an angle, represented by element 300, of slightly greater than 45° so that the light exits the surface of the flip chip and refracts in the direction toward the flip chip. The approximate light path, 402, is shown. This latter approach could reduce the overall footprint of the laser by making use of the area underneath the flip chip.

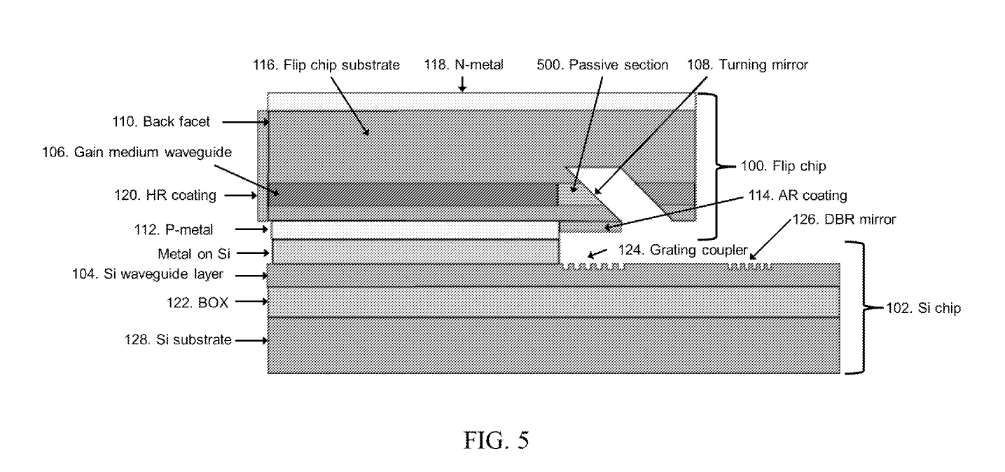

FIG. 5 shows a sideview schematic of the integrated laser where the flip chip incorporates so called active-passive integration. Since the area on the topside down surface (the surface of the chip from which the mode exits the flip chip) would likely contain a region free of metal to allow for the vertical emission of light from the chip, a small region of the active medium may not receive sufficient electrical pumping and therefore potentially introduce a source of optical loss in the laser cavity. To significantly reduce this source of loss, active-passive integration can be incorporated as illustrated in FIG. 5 so that the region free of metal is rendered passive. This passive section is represented by element 500 in FIG. 5. The active-passive integration can be carried out using a number of techniques including, but not limited to, quantum well intermixing (where quantum wells are selectively intermixed to alter the bandgap), offset quantum well (where quantum wells are removed selectively to form passive regions), butt-joint growth (where separate active and passive regions are formed with an additional growth step), selective area growth (where the growth rate is selectively altered using pre patterning so as to selectively alter the bandgap), or vertical waveguide (where multiple waveguides are grown in a vertical stack and light is coupled between these waveguides using vertical coupler tapers).

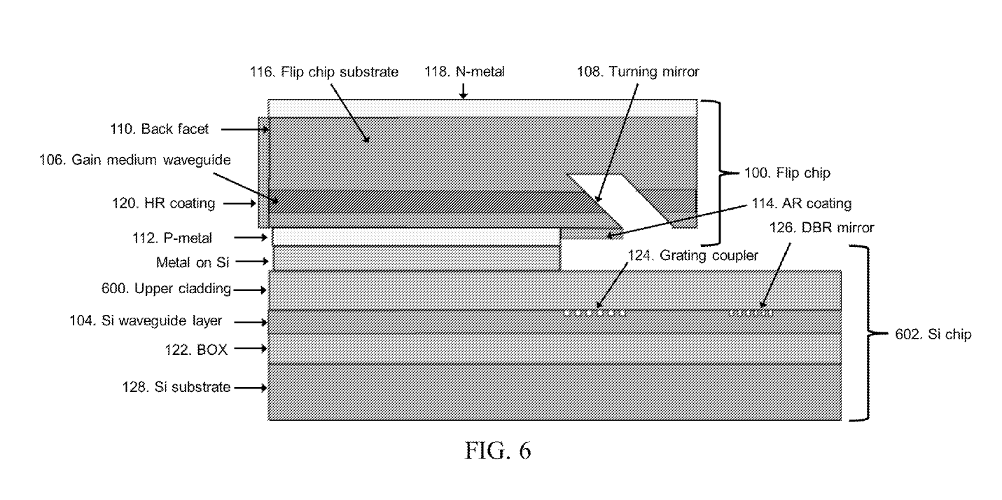

FIG. 6 illustrates another embodiment of the flip-chip bonding integration where the flip chip, 100, could be bonded to the SiO₂ overcladding layer, 600, of the Si PIC chip, 602, as opposed to directly to the Si waveguide layer. In this case, a metal bonding pad can be patterned on the overcladding of the Si chip, as shown in the figure. This could be the same metal layer that is used for the bond pads of the Si PIC, which likely contains aluminum (Al) metal. The bonding process could be carried out using either metal-to-metal thermocompression bonding or solder bonding. In an alternative embodiment, one of the direct bonding approaches could be utilized, that is to say, without using metals. In the embodiment illustrated in FIG. 6, the flip chip, for realizing a laser, would be positioned further away vertically from the Si chip. Therefore the exit point of the optical mode from the flip chip would likely be further from the surface grating coupler of the Si chip. The design parameters would likely differ in this embodiment in order to maximize the coupling efficiency between the two chips. For example, the optimum lateral position of the flip chip relative to the grating coupler would likely differ for this embodiment. The optical mode incident on the grating coupler may also be slightly larger in this case since the mode travels a larger vertical distance and therefore diverges to a larger degree. This increased mode size can potentially be advantageous for increasing the coupling efficiency to the Si waveguide through the grating coupler or for collimating the beam using integrated optics components. Bonding to the upper oxide cladding layer may also have some other advantages.

In the embodiment where the flip chip is bonded directly to the Si waveguide layer, either an air cladding would be utilized for the Si, which typically yields higher waveguide loss, or an opening would need to be formed in the upper oxide cladding in the regions where the flip chip bonding would be incorporated. The case of bonding to a metal bond pad on the upper oxide cladding, or directly to the oxide cladding without metals, may be simpler and also more compatible with the typical Si photonics processes. This could also allow for ensuring the entire Si waveguide structure is embedded in the oxide cladding and not exposed to air.

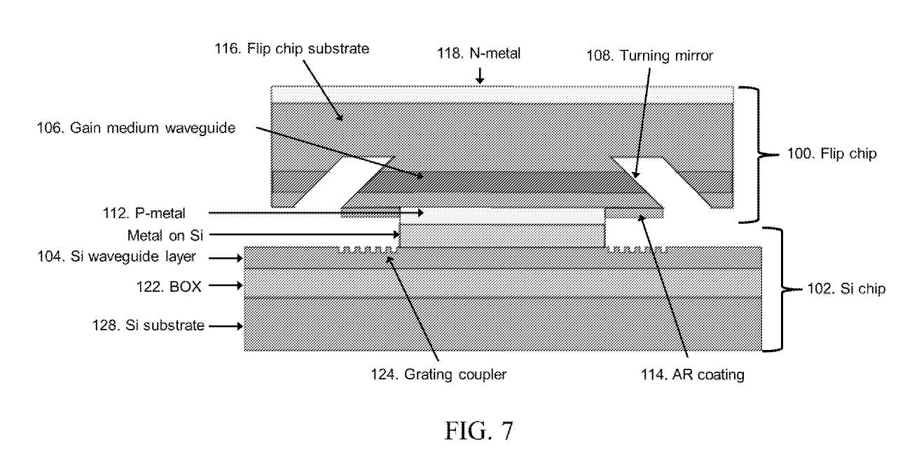

FIG. 7 illustrates an embodiment to realize an integrated SOA in the Si PIC where the SOA could be used as a preamplifier for a receiver, as a booster amplifier for a transmitter, or to overcome waveguide losses of the PIC. In this embodiment the flip chip has two turning mirrors to allow for a two-port device where light from the Si PIC is directed upward through a grating coupler and couples to the flip chip through the turning mirror. The light can undergo amplification as it propagates in the flip chip gain medium waveguide and then can be directed downward by a second turning mirror and then recouple to the Si PIC through a second grating coupler.

The turning mirrors in the flip chip can be identical apart from their orientation. An AR coating can be applied to both the entrance and exit surfaces of the flip chip, as in previously described embodiments, to minimize reflection back into the flip chip gain medium waveguide. In particular for a preamplifier SOA, as could be used for a receiver where the signal could be immediately amplified after coupling and prior to any demultiplexing or detection, a modified embodiment could be realized where the input light is coupled directly to the flip chip from say an optical fiber, then amplified, then coupled to the Si chip using the turning mirror and grating coupler. For a booster amplifier for a transmitter, where the signal would be amplified prior to exiting the chip, the light could be directly coupled from the gain flip chip to external elements, such as an optical fiber. These alternative embodiments can avoid one Si-to-flip chip coupling and can improve the overall sensitivity of the receiver or coupling efficiency of the transmitter.

For these alternative embodiments, the flip chip could be fabricated in such a way that one side has a cleaved facet with an AR coating applied for coupling from the optical fiber, and the other side contains an angled turning mirror for redirecting the light vertically. The AR coating would minimize reflections upon coupling and the gain medium waveguide could also be formed at an angle with respect to the cleaved facet to further minimize reflections.

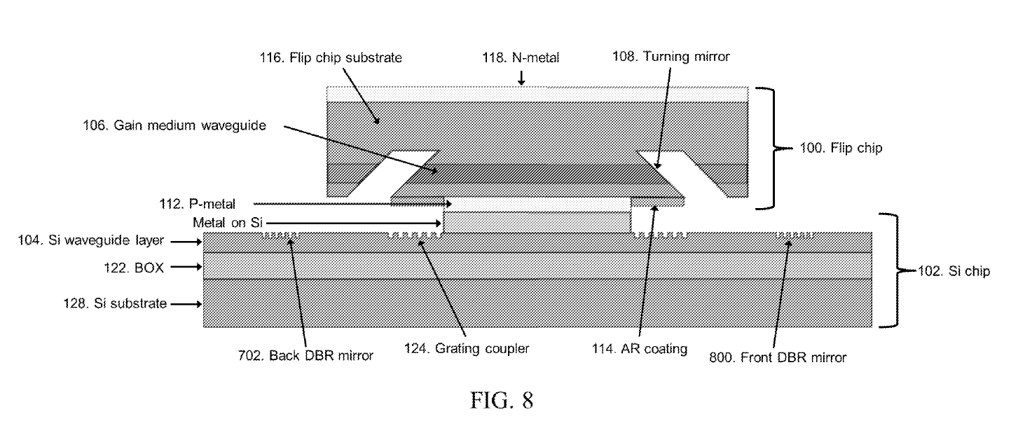

FIG. 8 shows an embodiment where the flip chip is fabricated with two turning mirrors to form a two-port optical device providing gain for a laser. In the configuration shown in FIG. 8 the laser is a two-mirror DBR configuration. As in the earlier laser embodiment, the DBR gratings are etched in the Si waveguide. The front DBR mirror, element 800, can be designed to have a reflectivity in the range of<5% to>90% depending on the requirements of the laser source regarding desired optical output power and laser linewidth. The back DBR mirror, element 802, can be designed to have a high reflectivity of>90%. In addition to the two-mirror DBR laser described, this embodiment, with two pairs of coupling elements (turning mirror and grating coupler), allows for other advanced integrated laser configurations such as, but not limited to, the digital supermode DBR (DS-DBR) laser, the sampled grating DBR (SGDBR) laser, and the super-structure grating DBR (SSG-DBR) laser. In all cases, the DBR grating mirrors could be fabricated in the Si waveguide layer as shown in FIG. 8. This embodiment could also be altered to allow for a symmetric laser design, where both mirrors have reflectivity of 50% and in this case light from this single gain element could be used for two separate light paths in a straightforward manner. Such an embodiment might be used in a spatial division multiplexing (SDM) application.

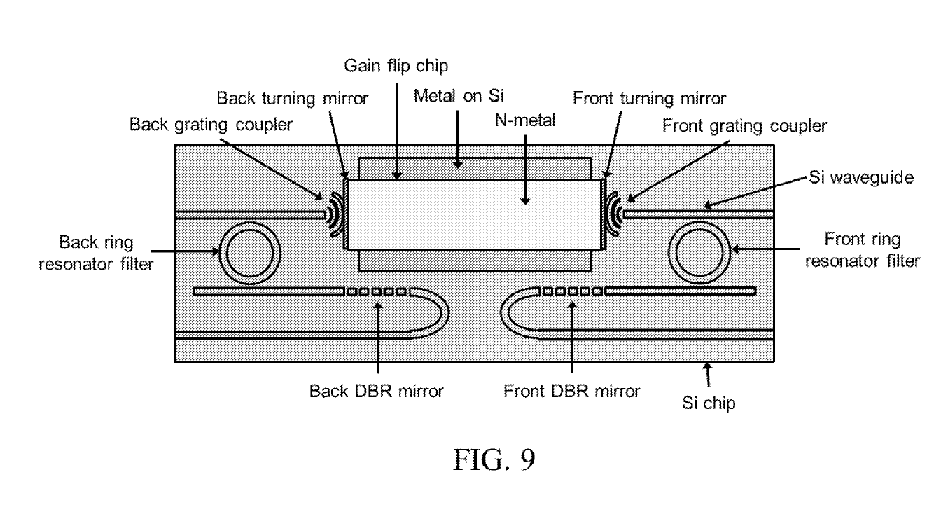

In a modified embodiment, shown in topview in FIG. 9, ring resonators can be incorporated for optical filtering within the laser cavity and DBR mirrors can be incorporated to close the laser cavity. A broadband etched or polished facet could also be used to close the cavity. The resonance frequency of the ring resonators determines the lasing wavelength. The ring resonators could be designed with different radii, therefore a different free spectral range, and a tuning mechanism can be incorporated such as heaters for thermooptic tuning. Heaters can be realized using a resistive metal layer above the Si waveguide or using Si itself as a resistor where doping is incorporated into the Si to allow for realizing ohmic contacts and a specific Si resistivity. With two ring resonators as shown, Vernier tuning could be utilized, where the rings are tuned so that the resonance wavelengths align at only one selected wavelength due to the differential free spectral range. The DBR mirrors can be utilized to close the laser cavity; however, broadband etched or polished facets can also be used. The back DBR mirror could be designed with fairly high reflectivity (>90%) and a broadband spectrum and the front DBR mirror with a lower reflectivity (in the range of 5-90%) and also a broadband spectrum.

This embodiment could be configured in a number of other ways. For example, a single ring resonator filter and a single DBR mirror could be utilized. The back end of the gain flip chip could then contain a cleaved or etched back facet with an HR coating for realizing a broadband reflection as in earlier embodiments, and only the front end would contain the etched turning mirror for coupling to the Si waveguide through a grating coupler formed in the Si waveguide layer. The ring resonator could be designed for a particular free spectral range and the resonance wavelength could again be tuned using an integrated heater to tune the lasing wavelength. The DBR mirror could be designed with a reflectivity in the range of 5-90%. This latter configuration would not have as large a tuning range as the former, which utilizes Vernier tuning, however the implementation is somewhat simpler in that only one turning mirror is required.

The two-resonator design shown in FIG. 9 could also be designed in a configuration where both the front and rear DBR mirrors have equal reflectivity so that light from the single gain medium could be used to generate a signal in two separate light paths, as described previously.

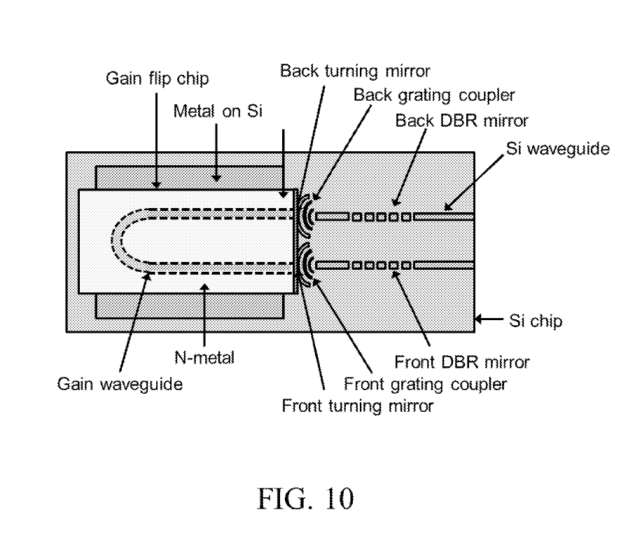

FIG. 10 shows a topview of a configuration for realizing a two-port optical device in the gain flip chip where the gain medium waveguide makes a 180° turn in the plane so that both vertical emission turning mirrors could have the same orientation and can be fabricated in one step. The gain medium waveguide is indicated by the dotted line. This embodiment could provide a means to reduce the cost of fabrication of the gain flip chip and also to realize a more compact laser structure that occupies less area. In the configuration shown in FIG. 10, two DBR mirrors are utilized to realize an integrated laser; however, this embodiment could also utilize ring resonator filters as in the previous embodiments. This embodiment allows for realizing a laser structure that consists of two filters, such as DBR gratings or ring resonator filters, allowing for a complex laser configuration, such as those described previously, while maintaining a simple fabrication process that requires only one step for realizing all of the turning mirrors. The 180° turn could also be realized in a passive region if active-passive integration were employed. This concept of active-passive integration will be described in later embodiments.

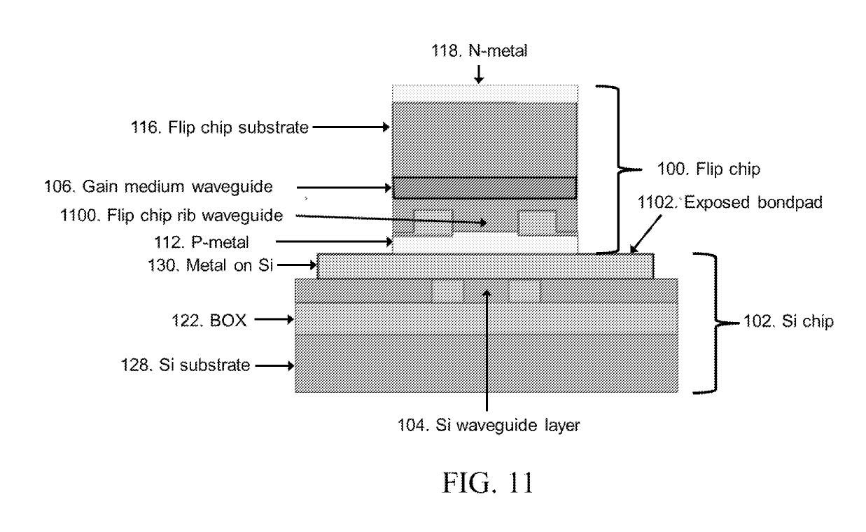

FIG. 11 shows a cross section view of the integrated laser to describe a potential layout of the metal pads for providing electrical pumping to the laser. As an example, in one embodiment the gain flip chip can be realized with a top down P-I-N structure on a conducting substrate. Therefore p-metal contacts can be formed on the topside of the gain chip and n-metal contacts formed on the backside of the chip after thinning. This chip could then be flip-chip bonded so that the p-contact bonds to a metal bond pad on the Si chip. The metal on the Si chip could extend out laterally, as shown in FIG. 11, to provide a means to access the p-electrode of the gain element. In this figure, a rib waveguide structure is illustrated for the gain flip chip, element 1100, however any type of structure could be used including, but not limited to, a buried ridge, ridge, strip, stripe, buried channel, or deeply-etched ridge. The metal on the Si chip, which is connected electrically to the p-metal of the gain flip chip, can then be accessed from the top as shown by element 1102. The n-electrode can be accessed directly from the backside of the gain flip chip, which is now facing up.

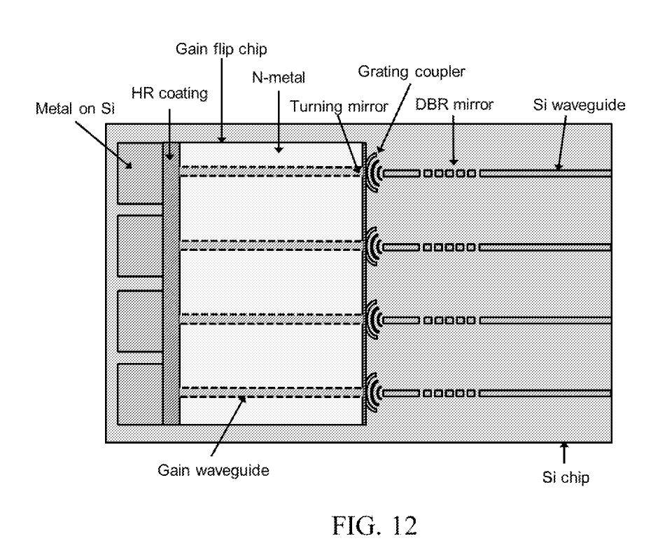

In a configuration to realize several integrated laser sources using the same gain flip chip, the metal bond pad on the Si chip could simply be made larger than the gain chip in the direction of waveguide propagation so that the bond pads extend out from under the gain chip. This embodiment is shown in FIG. 12 where the present invention is used to realize a photonic integrated circuit with four integrated laser sources, although this can be scaled to many more than four sources. In both cases, it is advantageous, although not necessary, to use a gold (Au)-free contact scheme, at least for the p-metal, and desirably for the n-metal, in order to make the gain chip compatible with the Si chip which is mated in the flip-chip bonding step. Direct bonding could also be utilized to avoid metals for the bonding process, as described earlier. For metal or solder bonding, contact schemes where the topmost layer of metal is Al are preferred so as to simplify the flip-chip bonding process to the Al-containing metal bond pads on the Si chip.

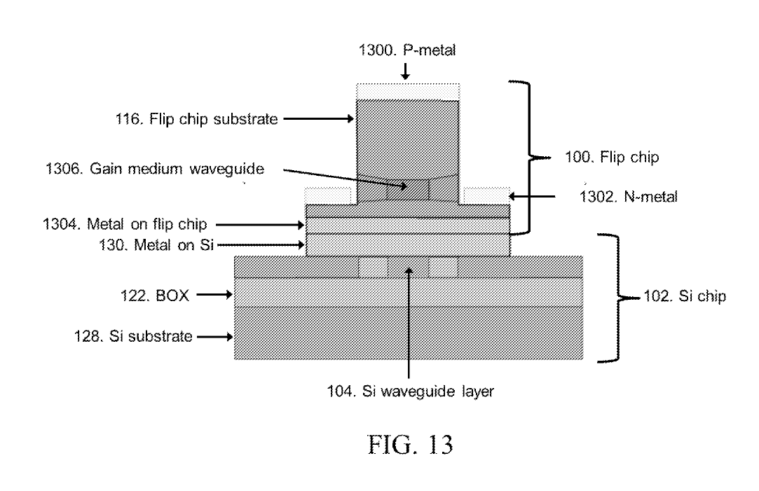

FIG. 13 describes a configuration of the integrated laser where the flip chip is designed to allow for the incorporation of backside contacts for both the p-and n-metal so that, once flip bonded, whether using metal (as shown in FIG. 13), solder or direct bonding, both the p- and n-metal electrodes (elements 1300 and 1302 respectively) are facing upward. A topside metal layer, element 1304, and if beneficial, a solder metal, could be deposited for a flip-chip bonding process. Alternatively, the gain flip chip could be directly bonded to the Si so as to minimize the distance between the exit surface of the flip chip and the grating coupler in the Si chip. This could be accomplished with an oxide-to-oxide bond, where a thin layer of oxide material is present on both the Si and gain chips, with direct wafer bonding, or with adhesive bonding. In this latter configuration, Au-containing metal stacks, which are more traditional for gain chips (made, for example, from a III-V material), can be used, and the topside metal, if used for flip-chip bonding and which would not make any active contact, could contain Al, which would be compatible with the Al-based metal bond pad common for Si photonics. Alternatively, other metals could be used such as, but not limited to, copper (Cu).

It could potentially be beneficial to use a top-down N-I-P structure as opposed to a more traditional P-I-N structure. The former case may reduce device resistance. The schematic shown in FIG. 13 is configured this way. The schematic also portrays a buried ridge style waveguide, pointed out as element 1306, which is particularly convenient to use for this N-I-P structure, although other waveguide structures could be utilized.

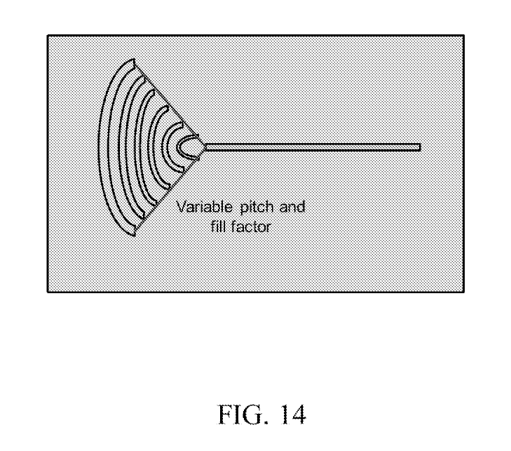

The efficiency of the light coupling from the gain flip chip to the Si chip is important for maximizing the efficiency of the laser. Using what has become fairly standard for Si photonics, 220-nm thick SOI technology, the efficiency of conventional grating couplers is fairly high, but these grating couplers were optimized for coupling from optical fiber. The mode of a conventional gain chip, such as, but not limited to, a III-V chip, is significantly different than that of an optical fiber; it is typically elliptical in shape, small, and characteristic of large divergence angles. In order to enhance the coupling efficiency, optimization of both the mode shape of the flip chip gain medium waveguide and the mode shape of the Si surface grating coupler can be pursued. In the following embodiments, that could firstly increase the coupling efficiency, the alignment tolerance of the flip-chip bonding step can also be improved. The grating can be made to have a pitch and duty factor that varies away from its center, as shown in FIG. 14, so as to create a better match of the mode of the grating coupler and that of the gain flip chip. In this way the grating coupler could exhibit a lens-like property that could compensate for large divergence angles of the optical mode from the flip chip. This general idea of apodizing the grating could tailor the grating coupler for the expected mode from the flip chip. The grating period and fill factor could be made nonuniform in both the direction of light propagation and the transverse direction (i.e. both the horizontal and vertical directions in FIG. 14).

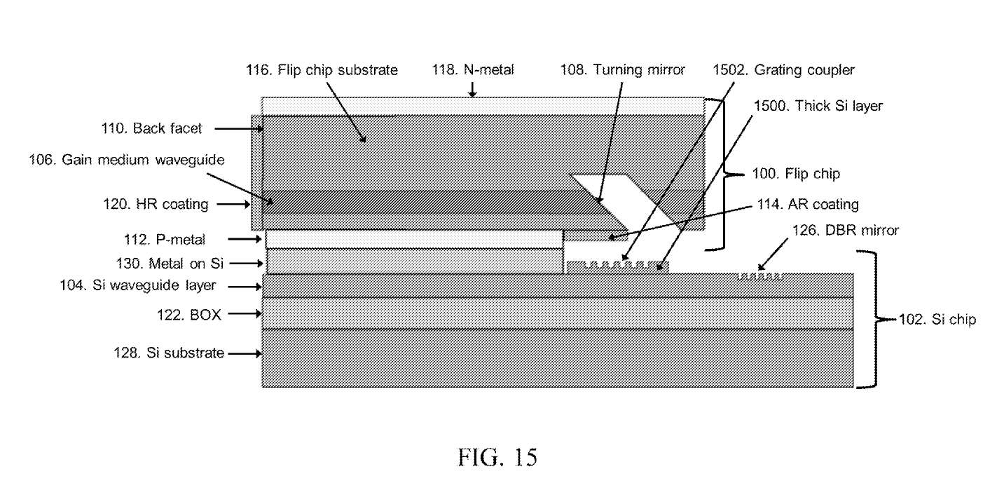

To additionally increase the coupling efficiency, the waveguide can be made thicker, by either using a thicker Si layer (for example greater than the conventional 220-nm thick Si) or by locally depositing polycrystalline Si (poly-Si), amorphous Si, single crystalline Si, and other high index material, in the region where the grating coupler would be formed. The case of locally increasing the thickness of the Si waveguide layer is shown in FIG. 15. Element 1500 represents a layer of Si that is deposited or grown on a conventional Si waveguide layer to realize a thicker layer in the region where the grating coupler, represented by element 1502, would be formed. The coupling efficiency can be significantly improved with a thicker waveguide layer. The grating etch as shown in FIG. 15 does not penetrate the underlying 220-nm thick Si, however, it can, and likely exhibits higher coupling efficiency that way.

Another means to increase the coupling efficiency from the flip chip to the Si chip is to alter the flip chip mode shape, size, and divergence. Spot-size converters could be utilized, as described earlier, to alter the mode shape, size, and divergence only in the vicinity of the turning mirror. Alternatively, the entire waveguide structure could be designed to uniformly propagate such a mode. This can be accomplished by utilizing a thick waveguide layer so as to increase the vertical dimension of the guided mode and realize a more circular mode shape that maintains lower divergence angles upon exiting the chip. Such a structure could be realized using a slab-coupled optical waveguide, a dilute waveguide, a buried waveguide, as well as a number of other structures that exhibit such modal behavior. The large and more symmetric mode of such structures would couple more efficiently to the grating coupler and also increase the alignment tolerance of the bonding step. Such an embodiment would also allow for higher power operation as the maximum achievable power is related to the power density of the optical mode. The thickness of the Si waveguide layer could also be increased for high-power applications.

In the case of integrating a spot-size converter in the flip chip to alter the mode size, shape, and divergence angles, a conventional waveguide would be utilized for the active region, likely exhibiting an asymmetric and diverging mode. Then a spot size converter is incorporated to increase the mode size, alter the mode shape, and reduce the divergence angles using any of the previously described spot-size converter technologies.

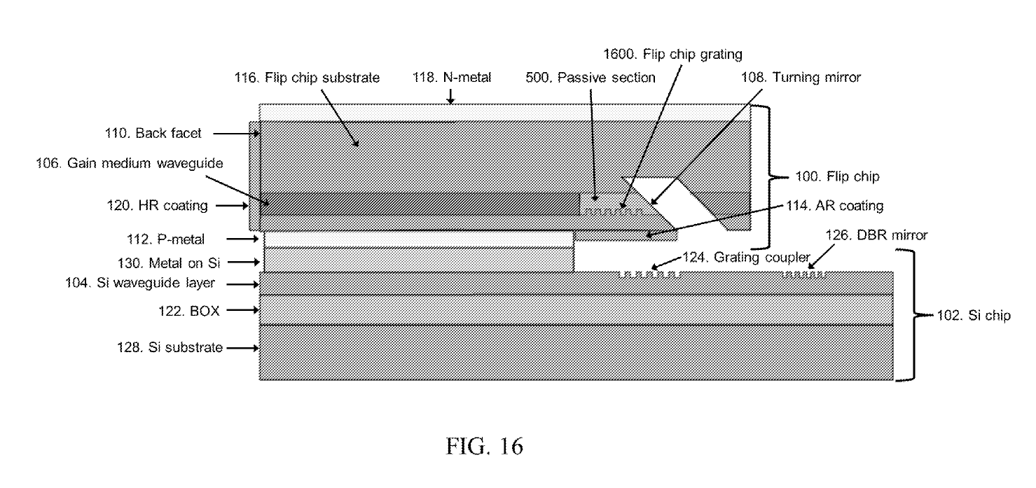

In another embodiment, a grating structure could be incorporated into the flip chip waveguide so as to alter the mode size, shape, and divergence prior to reflection from the turning mirror. In this case it could be beneficial, although not necessary, to exploit an active-passive integration technique, such as that shown in FIG. 5, to allow for realizing a passive grating region. This grating could be designed to diffuse the mode, increasing the size, altering the shape, reducing the confinement, and therefore allow for a reduction of the divergence angles so that the mode that exits in the vertical direction will couple more efficiently to the grating coupler. This implementation is shown in FIG. 16 where element 1600 represents the grating in the flip chip waveguide.

Instead of using an angled etched turning mirror, in another embodiment a grating could be formed in the flip chip designed for vertical emission. This is different from the grating described in the previous embodiments in that this grating would be designed to deflect the mode for vertical emission and would not necessarily require the assistance of a turning mirror, as in the embodiment of FIG. 16. In this case it would be beneficial, although not necessary, to also utilize active-passive integration so that the grating could be realized in a passive region. Any of the previously mentioned active-passive integration techniques could be utilized. This grating in the flip chip could be designed to also alter the mode shape so that it better matches to the mode of the grating coupler on the Si chip. The outcoupling efficiency of the grating in the flip chip can be improved by using an air cladding in the grating region and also by incorporating vertical DBR or other types of reflectors, the latter for increasing the extraction efficiency out of one surface of the flip chip. The air cladding can be formed by wet chemical etching. Following formation of the turning mirror, the cross section of the waveguide is exposed, and therefore the underlying layers would be susceptible to wet etching. The InP layers above and below the waveguide core would be undercut etched, thereby forming the air cladding. Such a structure would also benefit from a mode converter so as to transition from the InP-clad region to the air-clad region. This could be accomplished using horizontal and vertical tapers; wet etching could be tailored to form vertical tapers.

Other more advanced grating designs can improve the coupling efficiency. These advanced designs can be incorporated in the Si grating couplers or in, if used, the flip chip gratings. Blazed gratings, for example, can enhance the efficiency. In this type of grating, a special tooth or parallelogram shape is used.

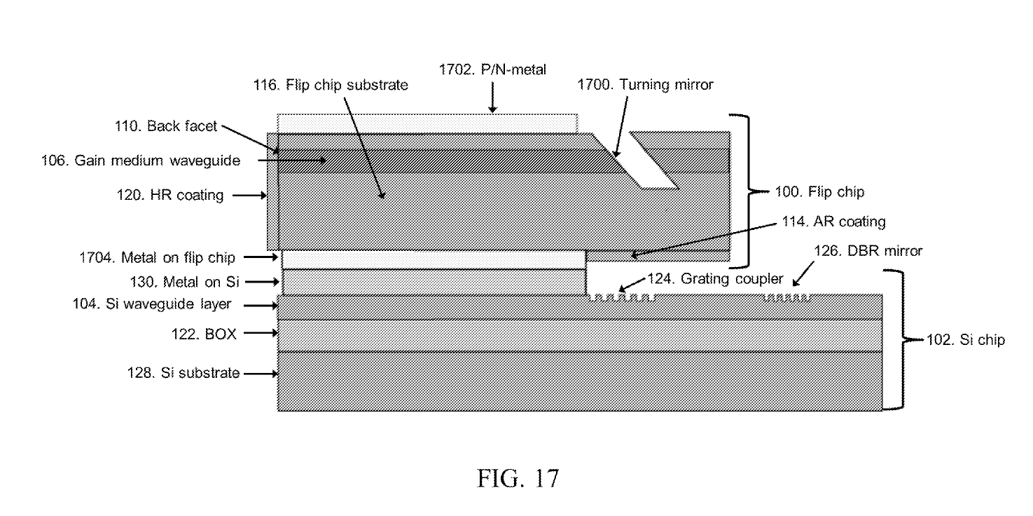

In another embodiment, the turning mirror in the flip chip can be made with a complementary angle so that the component emits light through the substrate, a so-called bottom emitting device, as shown in FIG. 17. In the case of an illumination device, that is to say a photodetection or modulation device, the device would be illuminated from the bottom; a so-called bottom illuminated device (such devices are discussed in later embodiments). When the flip-chip component is a gain chip that resides within a laser cavity, the flip-chip component is a bidirectional device in that it both emits and is illuminated. The bottom emitting (illuminated) embodiment could exhibit several advantages, some of which are described.

Referring to an integrated laser embodiment, in realizing the turning mirror in the gain flip chip using etching, it may be beneficial to etch a turning mirror with such a complimentary angle. Typically, using dry etching techniques, etch byproducts are more readily removed from the etching surfaces with such a complimentary angle, and this configuration may yield better local uniformity and uniformity across the wafer.

This bottom emitting (illuminating) configuration may also improve the coupling efficiency. Again referring to an integrated laser embodiment, the optical mode generated in the gain medium waveguide, after being directed downward by the turning mirror, will propagate through the thickness of the substrate and therefore will expand in size and change in shape. The larger size may be more conducive to coupling through the grating coupler in Si. This bottom emitting configuration could also incorporate any of the concepts already described such as a grating in the gain waveguide for reshaping the beam and reducing divergence angles.

The etched turning mirror with a complementary angle is represented by element 1700 in the FIG. 17. For this configuration it is sensible, but not mandatory, to use topside contacts for both the p-and n-metal, as was already described for another embodiment. Both topside metal layers are represented by element 1702 and the metal layer on the bottom side, which could be used only for the flip-chip bonding process, is represented by element 1704. Direct bonding without metals could alternatively be utilized, and this will be described in a later embodiment.

In an alternative embodiment, a lens could be attached to the bottom of the gain flip chip for reshaping and potentially focusing the mode as it exits the chip and before it couples to the grating coupler. Although a lens could in practice be integrated with the aforementioned top-emitting embodiments, it is more straightforward to integrate a lens on the bottom of the substrate, which will be planar, whereas the topside may not be planar.

Following topside fabrication of the gain chip, the wafer is typically thinned to approximately 100 μm, although thinner is possible, then polished, and then, if necessary, backside metallized. In the case of the flip-chip bonding integration, windows could be opened in the metal so that the light could exit, and, if applied, so that lenses could be attached or formed. Lenses could be formed directly into the flip chip substrate or could be attached in a backend step. Gallium phosphide (GaP) lenses, or other types of lenses, could be attached during the fabrication process while wafers are in full form or in a backend step, perhaps when chips are separated. GRIN lens elements could alternatively be utilized.

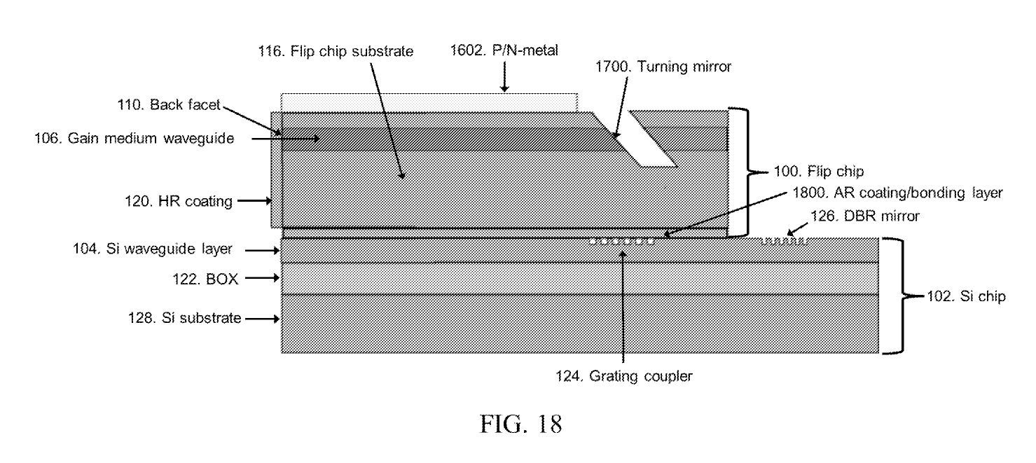

In a slightly different embodiment, the flip chip could be directly bonded to the Si chip. This direct bonding approach, more explicitly, would not rely on metals for the bonding and instead would utilize direct wafer bonding or bonding with an interfacial layer such as, but not limited to, an oxide layer or a polymer layer. The AR coating could potentially be used as the bonding layer and this would simplify the process a bit in that the AR coating would not require selective removal prior to bonding. This direct bonding approach would work equally well for both surface emitting and bottom emitting devices. This approach is presented in FIG. 18 for a bottom emitting device where element 1800 represents the AR coating/bonding layer. AR coatings typically consist of dielectric layers, so the AR coating could be employed for the bonding as well. The wafers could be brought into contact in a wafer bonding or die bonding system, and both temperature and pressure could be applied under a controlled environment. For this directly bonded approach, topside metals would likely be utilized for both the N-and P-contacts.

The directly bonded approach has some potential advantages. Firstly, the flip chip is placed close, vertically, to the Si chip, minimizing the propagation distance for the beam once it exits the flip chip and before it couples to the Si chip. Another advantage is that if desired, using the bottom emitting approach presented in FIG. 18, it is possible to co-fabricate the Si chip and flip chip at wafer level, prior to dicing of Si chips. This may reduce cost. For example, the Si waveguides can be formed on the wafer and flip chips can be attached to desired locations in dies on the wafer. The turning mirrors could then be formed. In this case, the turning mirrors could be directly aligned to the Si waveguides in a photolithography step. This process may demonstrate better alignment tolerance than the flip-chip bonding procedure used for other embodiments and would represent more of a monolithic than a hybrid process.

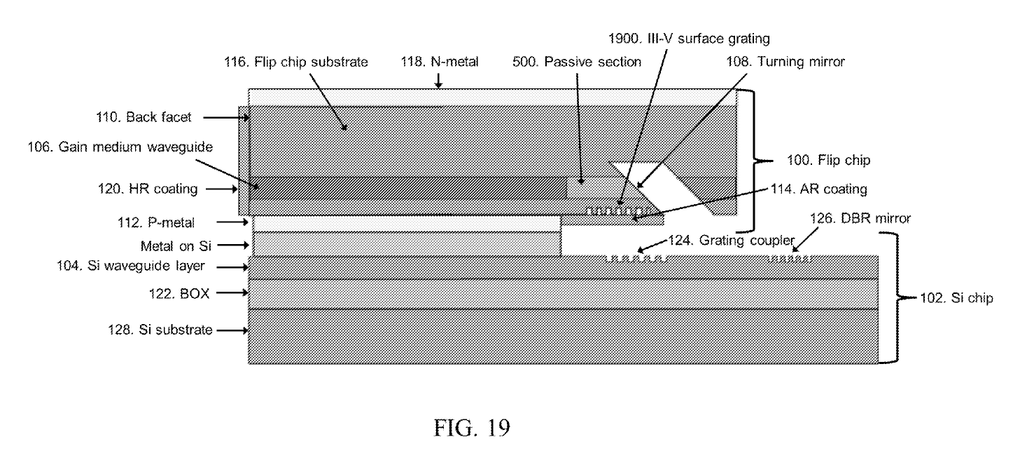

In another embodiment illustrated in FIG. 19, a grating structure could be formed on the surface of the flip chip for reshaping the beam as it exits the flip chip and for reducing the divergence of the beam. This grating, element 1900, could be designed specifically to reduce the divergence angle, which could directly improve the coupling efficiency for any of the embodiments presented. Alternatively, a plasmonic structure could be formed on this exit surface for the same objective. Since the grating or plasmonic structure is formed on the surface, this is far more simple to fabricate than if, for example, one were to form a similar structure on a vertical waveguide facet. If the divergence angle could be reduced to something more similar to that observed for optical fibers, the coupling efficiency would be drastically improved as well as the alignment tolerance.

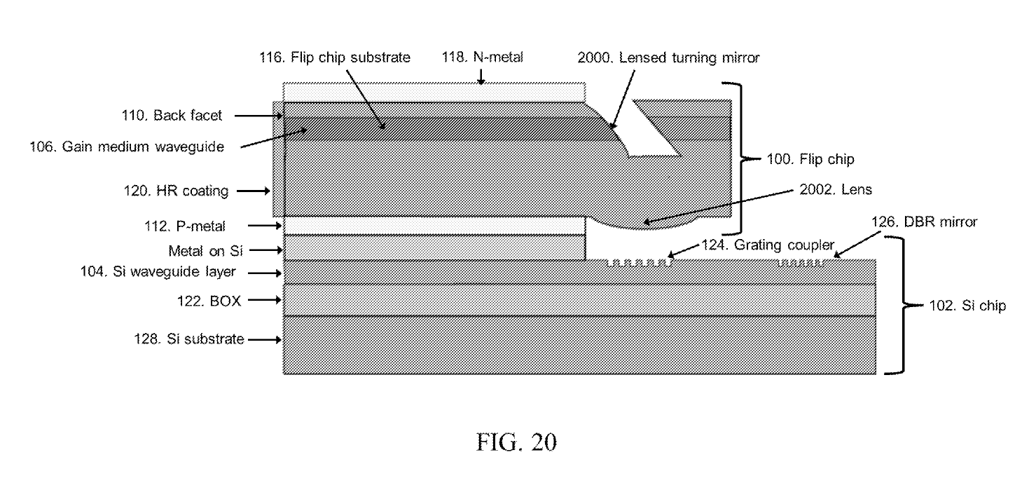

In addition to using gratings for reshaping the mode and reducing divergence, lenses could be incorporated on the turning mirror and the exit interface. As shown in FIG. 20, this embodiment could incorporate a lensed turning mirror, element 2000, for reshaping the mode during the total internal reflection process and reducing the divergence angle of the mode as it is redirected downward. This embodiment could utilize the bottom emitting approach. A second lens, element 2002, can be incorporated on the bottom emitting surface to again reshape the mode after it has propagated through the thickness of the substrate. These lenses could be formed with a tool such as an FIB to tailor their shape for the elliptical mode from the flip chip waveguide, or by some other means such as chemical etching processes.

Although this embodiment illustrates lenses formed in the semiconductor flip chip, other elements could achieve the same desired effect of reducing the divergence of the beam and controlling its shape and size to ultimately maximize the coupling efficiency to the grating coupler in the Si. It is desirable that the lens combination could be designed so that the mode that exits the chip is circular and symmetric, has a diameter similar to that of a single mode fiber, around 8-10 μm, and has a small divergence angle in the range of 5-10°. In this case, a conventional grating coupler, designed for fiber coupling, could be used for the vertical light coupling. In one embodiment, the first lens on the turning mirror could be used to reduce the divergence of the beam and reshape it so that once the beam arrives at the exit surface it has increased in size to approximately 8-10 μm. The second lens on the bottom side would reduce the divergence as the mode exits, desirably collimating the beam.

The same effect could be realized by attaching lenses to the backside that are formed in other materials such as gallium phosphide, or by utilizing a GRIN lens. A lens material could also be placed on a structure formed in the backside and cured into place with surface tension. The reshaping at the turning mirror could be accomplished by depositing a multilayer stack to realize a GRIN effect or by forming a grating directly into the turning mirror. And lastly the space between the vertical interface and the grating coupler could be filled with some material to enhance the mode matching.

In an alternative embodiment, a vertical facet could be formed in the flip chip waveguide in place of the turning mirror. This facet could either be utilized as a mirror for a laser or could be AR coated so that a reflective SOA is formed. The light could exit this facet and propagate for some distance either in air or in an oxide. The mode would diverge and increase in size. A separate turning mirror could be positioned some distance away from the facet to redirect the light vertically (either upward or downward). This turning mirror could have a curved shape so that it not only redirects the beam but also reshapes the beam upon reflection, potentially collimating the beam. This structure could be designed in such a way that the resulting vertically propagating beam is of a desirable size and shape for high coupling to the Si chip through a grating coupler. This embodiment can take on many forms and could incorporate elements from many of the other embodiments described. The space between the reflective SOA or laser front facet and turning mirror can be formed by dry etching, by wet etching, or by FIB. The turning mirror, which could be made curved, could be formed by etching and mass transport, by FIB, or could be attached. Alternatively, a non-curved angled mirror could be realized by etching or FIB and then a GRIN lens could be deposited on the surface.

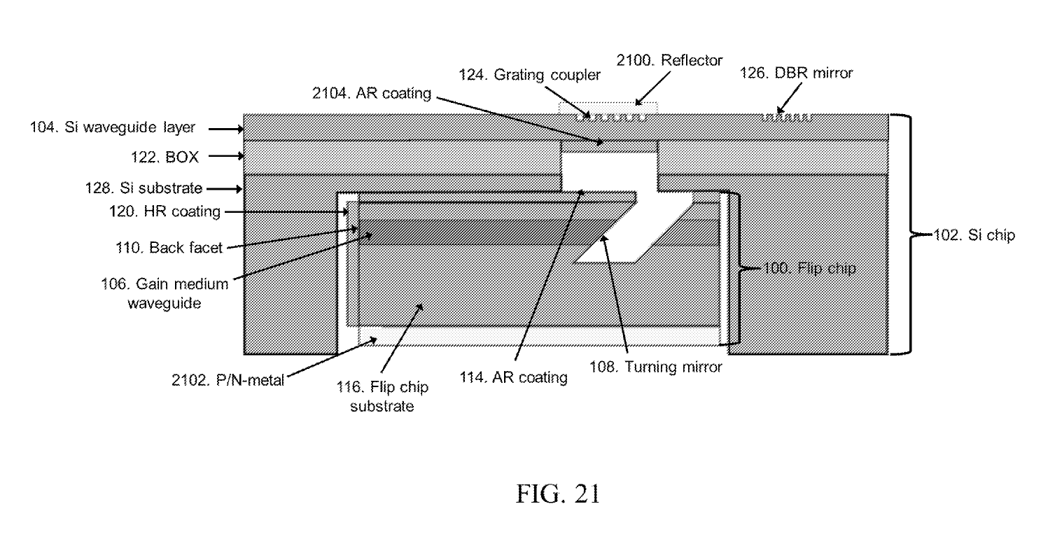

In another modified embodiment, illustrated in FIG. 21, a flip chip with turning mirror is attached to the backside of a Si substrate in a recessed opening formed by etching so that the light couples to a grating coupler formed on the topside of the Si waveguide layer. The flip chip is attached to the Si substrate in the recess, and an additional smaller recess is formed in the region where the light couples from the flip chip to the Si waveguide via the grating coupler. An advantage of this embodiment is that a reflector could be formed in a straightforward manner above the grating coupler, as illustrated by element 2100 in FIG. 20 to increase the coupling efficiency of the grating coupler. In this embodiment, both P-and N-metal contacts are formed on the backside of the flip chip as illustrated by element 2102 and the flip chip is attached by directly bonding to the Si chip. An additional AR coating can be formed on the backside of the Si waveguide to reduce reflection at the Si interface, as illustrated by element 2104. For this embodiment, it would be advantageous to incorporate some elements from other embodiments as well, such as a lens, grating, or GRIN lens, for reshaping the beam exiting the flip chip and reducing the divergence of the beam. A flip-chip waveguide structure with low divergence could also be incorporated.

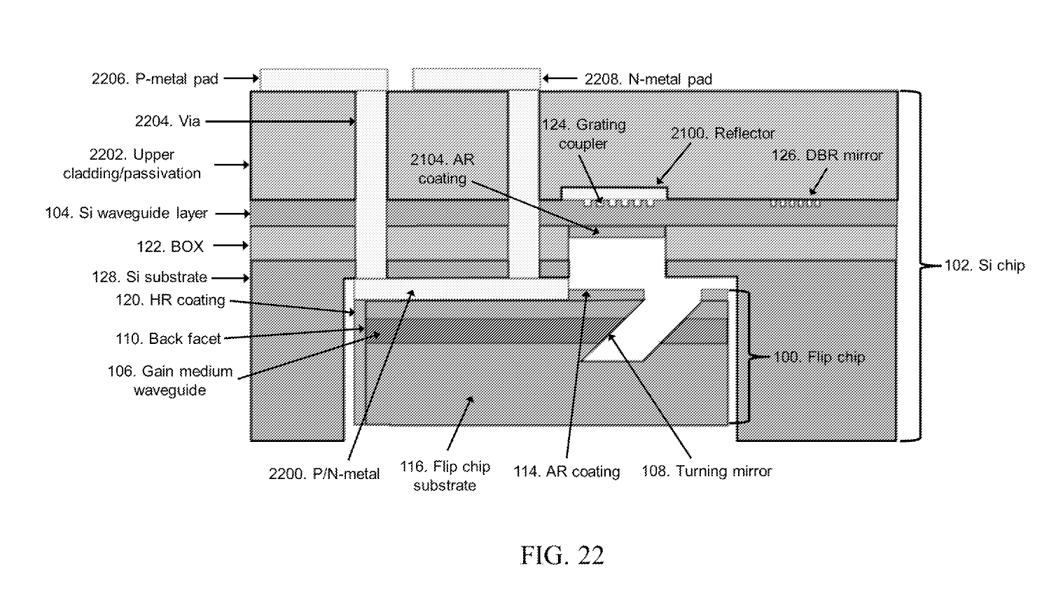

A flip chip could also be attached from the backside of the Si chip in a recessed opening using flip-chip bonding as shown in FIG. 22. The P- and N-metal contacts, illustrated by element 2200, are formed on the topside of the flip chip, which is then bonded to the backside of the Si in the recess by thermocompression or solder bonding. This structure also contains the smaller recess for the light coupling along with AR coating on the backside of the Si waveguide layer. To contact the flip chip from the topside of the Si chip, vias and topside metal contacts can be formed as illustrated in FIG. 22. These structures, with the flip chip attached to the Si substrate from the backside, exhibit efficient heat dissipation properties since the heat generated in the active region of the flip chip would spread into the Si substrate and then down to the heat sink upon which the Si chip is attached. The embodiment of FIG. 22 also has the advantage that the flip chip can be driven electrically from the topside of the Si chip in the same manner as other Si photonic components, such as optical modulators, thereby simplifying the packaging.

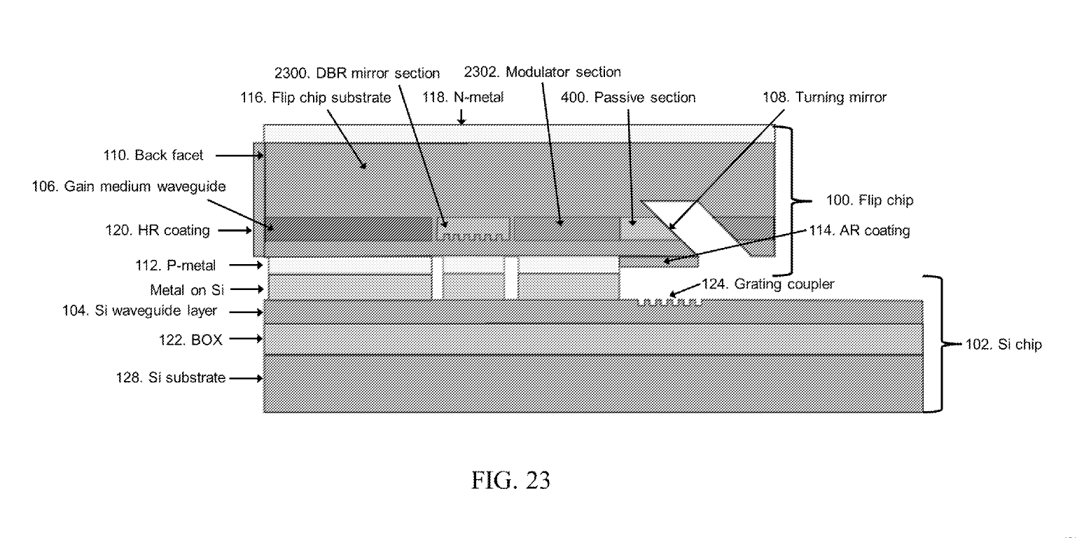

The vertical light coupling integration could also be utilized to integrate an externally modulated laser (EML) chip. In this case the entire laser structure and an optical modulator would be contained within the flip chip. The modulator could be an electroabsorption modulator (EAM) or Mach-Zehnder modulator (MZM). As in previous embodiments a turning mirror could be incorporated in the flip chip to redirect the light vertically and allow for coupling to the Si waveguide through a grating coupler. This embodiment is shown in FIG. 23 where element 2300 represents the DBR mirror section and element 2302 represents the modulator section. In this particular embodiment, the laser cavity contains a back HR-coated mirror facet, a gain section, a DBR mirror section (where the DBR mirror section has its own independent metal pad for wavelength tuning). To integrate gain, modulator, and passive sections (the latter for the DBR mirror as well as a short passive region near the turning mirror) an integration technique similar to some of the active-passive integration techniques described could be utilized. Different sections of the device could be electrically isolated using ion implantation to allow for independent control. The same type of region could be used for the modulator and passive regions. Or in a slightly more complex form, a separate type of region could be used for the modulator section so as to simultaneously optimize the modulator efficiency and the passive loss.

One advantage of such an embodiment, integrating an EML flip chip, is that the entire laser-modulator structure can be contained in the flip chip and therefore it would not be necessary to fabricate DBR mirrors or other types of filters in the Si. This simplifies the fabrication of the Si chip at the expense of a more complicated flip chip. The laser performance may also be improved compared to an embodiment where the laser cavity includes components in the Si chip. Also, III-V modulators are far more efficient than Si modulators, therefore if a III-V EML chip is utilized, the drive power required for modulation would be lower and the total device footprint could be significantly smaller.

In the embodiment shown in FIG. 23, separate metal pads are fabricated for the gain, mirror, and modulator sections where these pads can be used in a flip-chip bonding process. If the EML chip were instead directly flip-chip bonded to the Si or direct wafer bonded to the Si, both the n-and p-metal pads could be realized from the backside of the chip and this may be beneficial especially in realizing a high-speed interface for the modulator device.

In alternative embodiments, a distributed feedback (DFB) laser could be incorporated as the laser of the EML flip chip, or any other DBR lasers (including two-mirror DBR lasers) could be incorporated.

In a modified embodiment, the flip chip may contain photodetector regions so that all active components (laser, amplifier, modulator, and photodetector) could be realized in the flip chip. In this case the Si would contain only passive photonic components, and could contain electronic components. This embodiment would further simplify, and reduce the cost of, the Si chip at the expense of a more complex flip chip. The flip chip, however, may not necessarily be any more complicated than the flip chip in the embodiment shown in FIG. 23, because the same regions used for gain (for lasers and amplifiers) could be used for photodetection.

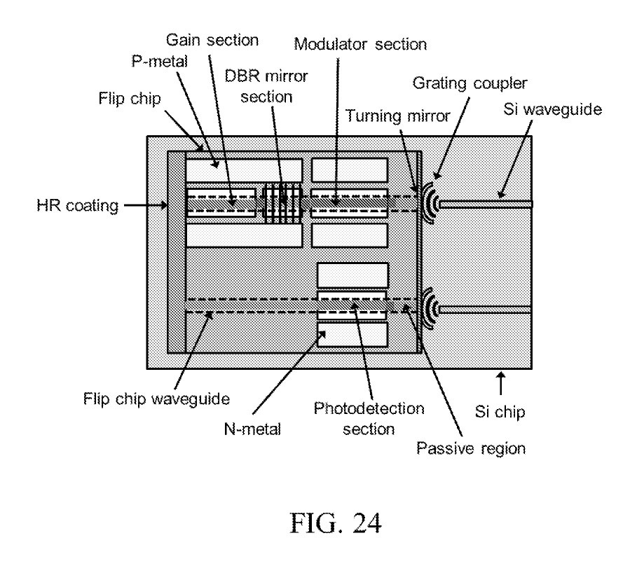

As an example, depending on the overall architecture of a PIC, say a transceiver, either one flip chip containing all active components could be integrated, or separate flip chips, one for say transmit and one for say receive, could be integrated. FIG. 24 shows an embodiment with one flip chip containing all active components integrated onto the Si chip where grating couplers are used for interfacing both the transmit and receive components of the flip chip to the Si chip. One advantage of this embodiment is that all of the active components come from one flip chip fabrication and only one flip chip is bonded for each transceiver, so the overall device footprint would be smaller and the integration would be more cost effective. The illustration in FIG. 24 shows only one laser and one photodetector for simplicity, however, a transceiver may contain several of each of these components for transmit and receive functionality. In the case of the laser-modulator transmitter component, the flip chip couples light to the Si chip through the Si grating coupler. In the case of the photodetector receiver component, light would be coupled from the Si chip through a grating coupler to the flip chip where the light would absorbed in a photodetection section. Other types of PICs may also be realized with this approach where either one or more flip chips containing active components are bonded to Si chips.

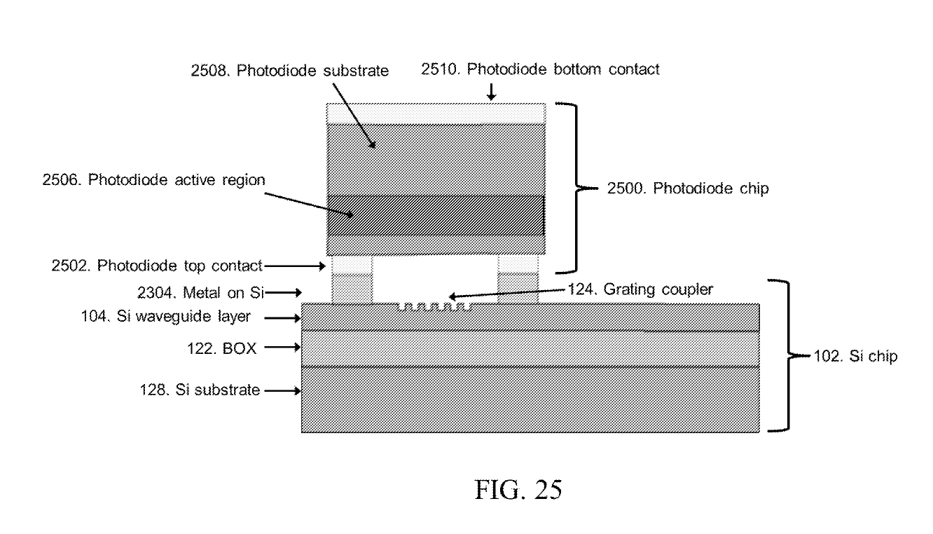

In another embodiment, surface illuminated components could be integrated as opposed to waveguide components. This could be particularly beneficial, for example, for integrated photodetectors for receivers. Surface illuminated photodetectors, especially PIN photodetectors, are inexpensive and demonstrate high performance. These could be integrated using flip-chip bonding integration (or direct bonding integration) and light could be coupled from Si waveguides to these chips through a grating coupler. For the receive aspects of a transceiver, signals could be coupled to the Si waveguides and undergo passive functions such as polarization rotation, splitting, and filtering, and then couple to the vertically illuminated photodetectors through grating couplers. The grating coupler design is tailored in this case for integrating surface illuminated components. This integration technique is especially beneficial when APDs are used as photodetectors. APDs generally have higher sensitivity and therefore can improve the performance of, for example, optical links employing transceivers. APDs are difficult to fabricate in waveguide form, however, are readily available in surface illuminated form. Light could be coupled from Si waveguides to a surface illuminated APD using a grating coupler. FIG. 25 illustrates the integration of surface illuminated photodetectors such as PIN-PDs and APDs using the vertical light coupling integration technique. In this embodiment, flip-chip bonding with metals or solders is employed. A ring contact could be used on the illumination side as shown in FIG. 25 where element 2500 represents the PD flip chip. Elements 2500 and 2502 represent the PD top contact and metal on the Si respectively. This could be patterned in a ring configuration, and the Si metal could be made larger in some region to allow access to the metal contact from the top. Element 2506 represents the PD active region, 2508 the PD substrate, and 2510 the PD bottom contact. Although this configuration shows a topside down flip-chip integration approach, a bottom-side down approach could be used as well, in which case the PD could be illuminated from the backside. In a modified embodiment, the PD chip could be directly bonded to the Si, in which case both the anode and cathode metal could be incorporated on one side (on the backside in the case of topside down bonding integration). Lenses or other focusing elements could also be incorporated on the Si or on the surface of the PD to increase the coupling efficiency to the PD and therefore the responsivity.

The surface illuminated photodetectors could be especially suitable for applications employing multimode fiber interconnects. In this case, light could be directly coupled to the photodetector.

The architecture of the flip chip and the Si chip can vary without departing from the scope of the invention, such as vertical light coupling for 3D photonic integration using grating couplers, lenses, and turning mirrors. The Si waveguide architecture could employ a significantly thicker Si waveguide layer, which would increase fabrication tolerances.

For some applications, it would be beneficial to encapsulate the entire flip chip in some material such as, but not limited to, an epoxy. This could be carried out after the flip-chip integration and would be beneficial for reducing packaging costs.

The vertical light coupling integration could also be employed in another embodiment to integrate optical modulator structures fabricated on other flip chips. These other chips could be fabricated from any material. Any of the previous embodiments could be utilized for vertical coupling from the Si waveguide to a modulator chip; for example, turning mirrors, gratings, and lenses could be incorporated in the modulator chips for coupling light from the Si to the modulator chip and from the modulator chip to the Si chip. The modulator has an optical input and output, so could resemble the optical amplifier or tunable laser structures presented in the embodiments of FIG. 7-10. The choice of modulator chip could depend on performance requirements. InP, GaAs and LiNbO₃, for example, offer some performance benefits over Si modulators.

If Si or silicon germanium (SiGe) modulator performance is sufficient, one may elect to integrate Si or SiGe modulators fabricated from separate chips to reduce manufacturing costs. In the case of Si or SiGe on say Si, it may be sensible to interface the two Si chips using grating couplers fabricated in both chips. This could be used as a utility for 3D integration of different Si chips, for example one which may contain active components and the other which may contain passive components. This could also be used in the case where perhaps passive Si components are fabricated in one chip for passive functionality and routing, and active components are fabricated in a Si chip that also incorporates electronics.

In an alternative embodiment, surface illuminated modulator structures could be integrated using the vertical coupling approach. This could be carried out in a similar manner to which surface illuminated photodetectors are integrated except that two grating couplers would be required, one for input and one for output, and the illumination angle would be such that the light couples from the Si chip through a grating coupler to the surface illuminated modulator, passes once through the active region, reflects, passes through the active region a second time, then exits the chip and couples to a new grating coupler. One advantage of this scheme is that the modulator footprint would be small and the coupling efficiency would be high.

For transceiver applications, integrated lasers realized with the vertical light coupling technology can be either directly modulated or externally modulated. FIG. 25 shows an example transceiver chip where light from a single integrated laser source is split four ways and then externally modulated by Mach-Zehnder modulators (MZMs). In the embodiment shown, a DBR mirror is incorporated in the Si waveguide for realizing the second reflector for the laser cavity, where the first reflector is provided by a HR-coated facet of the gain flip chip. However, any of the embodiments described could be employed here, including, but not limited to, the embodiment utilizing ring resonators for filtering, or the embodiment incorporating a two-mirror DBR laser design. In the embodiment shown in FIG. 25, data can be encoded on each of the four paths using the MZMs, and then the signals could be coupled to either a fiber array with four fibers or to a multicore fiber with four cores. If each MZM were modulated at 25 Gb/s, this embodiment would yield a 100-Gb/s capacity transmitter.

A receiver could also be integrated on the chip in a number of ways. Ge PDs or ion implanted PDs could be integrated in the Si process. Or photodetection elements could be realized in the flip chip using the same medium used for gain in the laser cavity as was described in the embodiment illustrated in FIG. 24. Passive elements such as couplers and splitters could be integrated in the Si waveguide layer. Such a transceiver could also be scaled to a larger number of lasers and photodetectors to increase the data carrying capacity. Additionally, surface illuminated photodetectors, such as PIN-PDs or APDs, could be integrated in the manner described in the embodiment shown in FIG. 25 to improve the sensitivity of the receiver.

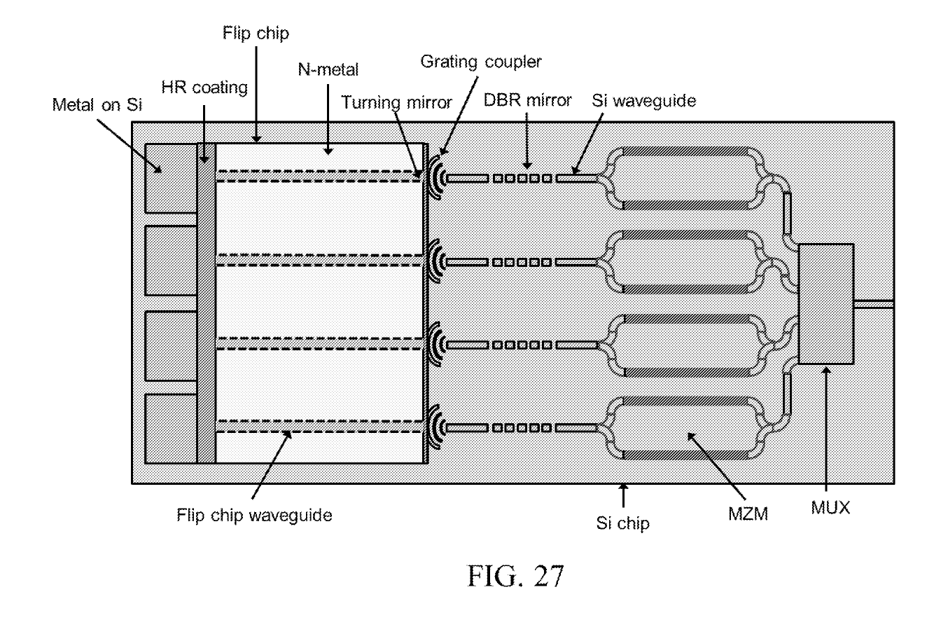

FIG. 27 illustrates a transmitter where four separate laser sources are realized using the vertical light coupling integration technique to employ wavelength division multiplexing (WDM). In this way, the light from each laser source could be either directly modulated, or externally modulated using MZMs as shown in the figure. If each MZM generates a 25-Gb/s signal, in the case of external modulation, then the total data carrying capacity of the transmitter would be 100Gb/s. This capacity could be scaled by increasing the number of lasers, which is straightforward with this laser integration technique. In the embodiment shown in FIG. 27, the signals are combined using a multiplexing (MUX) element such as a multimode interference (MMI) coupler, an AWG, or an echelle grating. Photodetectors and passive components could be integrated on the same chip to realize full transceiver operation using any of the previously described techniques.

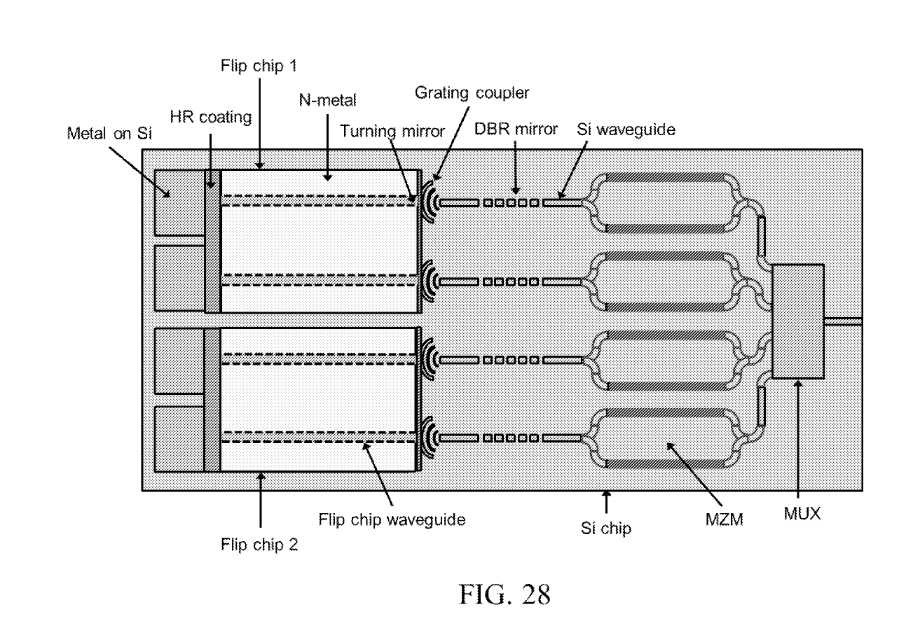

FIG. 28 illustrates a slightly different embodiment where two separate flip chips are integrated to realize a four-laser transmitter for coarse WDM (CWDM). With CWDM, the wavelength separation can be fairly large, for example, 20 nm. This poses a challenge because although it is straightforward to realize four filters spaced by 20 nm, for the case of a four-laser transmitter, the gain-bandwidth of common gain media is typically not large enough to support this spacing. Therefore, two separate gain flip chips could be integrated, with each flip chip fabricated from separate material with optimized gain spectrum is centered appropriately.

In order to avoid the use of multiple chips to span a WDM spectrum, a novel QW or QD structure could be realized with a sufficiently wide gain spectrum in a single flip chip.

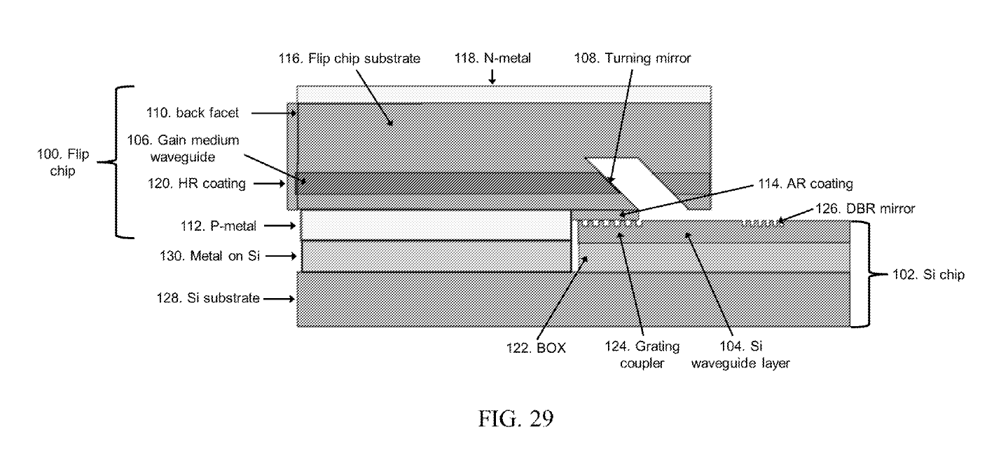

In another embodiment illustrated in FIG. 29, the flip chip is flip-chip bonded directly to the Si substrate. To access the Si substrate, a recess can be formed in the upper cladding, then the Si waveguide can be etched, then the BOX can be etched. This enables significantly improved heat dissipation as the heat generated, for example, in a RSOA chip, would diffuse downward and into the Si substrate. When the flip chip is bonded to the Si waveguide layer directly, or to the top of the upper cladding layer, the heat generated in the flip chip would not flow efficiently into the Si substrate due to the BOX layer, which is a thermal insulator. This concept of bonding the flip chip directly to the Si chip can be applied to any of the other embodiments. This also has the advantage that the exit surface of the flip chip can be positioned closer vertically to the grating coupler, which could improve the coupling efficiency.

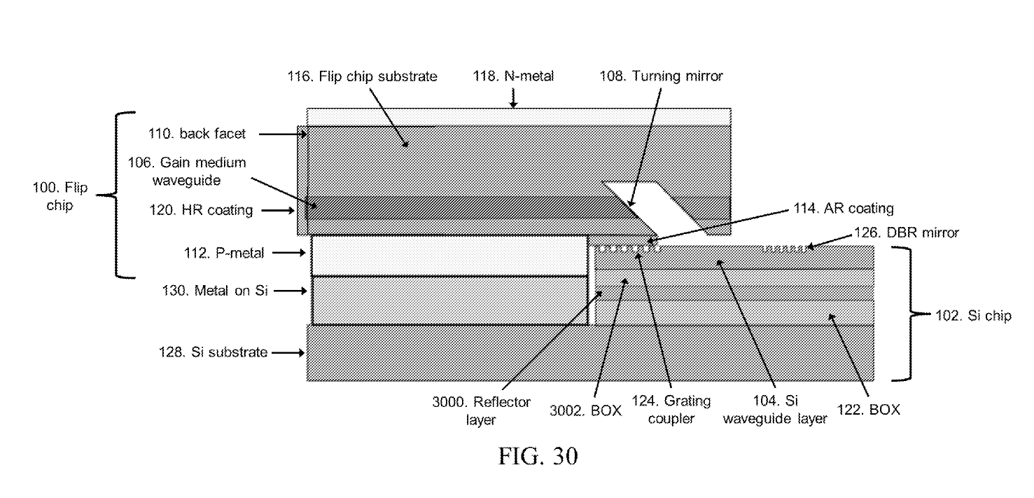

In all embodiments, advances in the grating coupler technology and design could be applied to increase the coupling efficiency between the flip chip and the Si chip. One example would be the use of double SOI, which contains two SOI layers. In the embodiment illustrated in FIG. 30, double SOI could be utilized to incorporate a reflector layer below the Si waveguide layer to recover light that transmits through the grating coupler. The spacing between the Si waveguide layer and the lower Si layer is optimized to reflect the light transmitted through the grating coupler so that it is recombined with the light directly coupled into the Si waveguide. Designs can incorporate more than one layer to form a DBR reflector.

Although primarily Si waveguide layers and grating couplers have been used as examples in the present invention, the light coupling technique can apply to any waveguide technology. Another example would be the integration of active waveguide structures such as those based on, but not limited to, InP, with silicon nitride (Si₃N₄) waveguides. The grating coupler could be formed in the Si₃N₄ waveguide and light would be coupler from the InP to the Si₃N₄ waveguide. Such a Si₃N₄ structure could be formed directly on a SOI structure and the Si waveguide could serve as a separate waveguide layer and as a reflector layer so as to recover light transmitted through the grating coupler and increase the overall coupling efficiency in a similar manner to that presented in the embodiment in FIG. 30.

In another embodiment, a DBR or DFB laser could be integrated using the vertical light coupling technique where the DBR or DFB laser chip contains a turning mirror for vertical light emission and the light from the laser is coupled to the Si chip using a grating coupler.

In another embodiment a comb laser source could be integrated using the vertical light coupling technique to provide a number of laser lines from a single gain chip. This comb laser could realized as a short-cavity multimode laser that has a particular mode spacing, or could be realized with multiple sections for balancing the power of the lines produced from the laser. The comb laser source, which could be based on QW or QD material, could be used for WDM transmission, or for WDM/dense WDM (DWDM) for on-chip applications.

In a modified embodiment, a QD gain chip could be used as a reflective SOA. This single gain medium could be incorporated into several laser cavities whereby the light from the reflective SOA chip is either split into several paths, each containing a filtering function such as a DBR mirror or the light is fed to series of ring resonator filters through a common bus and whereby the ring resonators have DBR mirror on the opposite ports to close the laser cavities.

In another embodiment, concerning the integration of waveguide-based flip chips, for example, the flip chip would incorporate a waveguide design that maintains a fairly circular and symmetric mode and that exhibits a small divergence angle. Such modal behavior can be realized in a number of ways including, but not limited to, a diffuse waveguide or a low-confinement rib waveguide where the core is thick. For the latter, a thick waveguide core could still realize single mode behavior if the rib width and thickness are designed accordingly. Either the entire flip chip would comprise such a waveguide structure, or a spot-size converter could be integrated so that only the output section near the turning mirror contains this type of waveguide structure. Such modal behavior would significantly improve the coupling efficiency from the flip chip to the Si chip through the grating coupler, and would also improve the alignment tolerance.

In all embodiments, the Si chip could contain electronic integrated circuits that could be used for transmitter or receiver functions. Alternatively, an electronics chip could be flip-chip bonded to the Si chip. The electronics could provide drivers for the optical modulators or directly modulated lasers, signal conditioning, amplifiers in particular for receivers, and signal processing functions.

In another embodiment, the grating coupler in the Si chip could be designed as both a coupler and a reflector so that light from the reflective SOA reflects at the grating coupler by some amount and is also coupled into the Si waveguide through the grating coupler.

The vertical light coupling approach could be applied to building PICs for many applications, including, but not limited to, transceivers for optical communications, sensors, microwave photonics, and biophotonics. Some examples include photonic network-on-chip applications for optically interconnected multicore processors, short-reach optical links for data centers, transceivers for coherent communications including integration of lasers for transmitters and as local oscillators for receivers, and narrow linewidth lasers.

The present invention could also utilize 2D grating couplers whereby the grating coupler is designed for polarization splitting (or combining). As an example, if it is desirable to combine two lightwaves, one that is TE polarized and one that is TM polarized, and that are propagating in planar waveguides, such as Si waveguides, a 2D grating coupler could combine these lightwaves and then couple them to a bonded PD structure.

It is understood that for optimal coupling, the grating may have to be apodized, rather than having uniform pitch and duty cycle. For fiber grating couplers, the apodization is typically designed by assuming that the grating is one-dimensional because the divergence of light in the lateral dimension, along the grating grooves, is small. Consequently, the main optimization objective is to adjust the nominally exponential-like leakage of light out of the grating to better match the Gaussian-like distribution of the optical fiber mode. Rather than being exponential in the direction of propagation, a more optimal distribution of the leakage factor can be obtained. Once the desired distribution of the leakage factor is determined, the grating pitch and duty cycle are adjusted to obtain it. Further improvement in the optimization procedure can also be carried out by using the calculated distribution of the leakage factor only as a starting point for a subsequent genetic-algorithm search routine, combined with numerical optical simulation software. Besides the grating pitch and duty cycle, the grating depth may be apodized as well. The grating coupler design for coupling from integrated waveguide structures may follow a similar approach for the embodiments containing spot-size converters, however, may differ for coupling from waveguides that have highly diverging beams.

Following the design of grating apodization using one-dimensional optical simulation software (for example mode expansion or finite-difference time-domain software) as well as a genetic algorithm, the design of the grating geometry in the lateral dimension can be performed using three-dimensional optical simulation software (such as those based on mode expansion or finite-difference time-domain methods). One important aspect of the grating design in the lateral dimension is the design of a grating geometry and/or a waveguide taper that would focus light from a relatively wide grating (typically in the range of 10-20 μm) into a narrow optical waveguide (typically 0.2-1 82 m) that can be used for on-chip routing of the light. If the grating grooves are not curved but rather straight, the focusing can be carried out by coupling the light from the grating into a waveguide of similar width and tapering the waveguide width laterally so that light is adiabatically focused into the small mode of the routing waveguide. Alternatively, the grating grooves can be curved so that the focusing action occurs within the grating itself.

The grating may be designed so that the grating grooves have elliptical shapes, which minimizes the reflection of light coupled into the grating. Minimization of grating reflection is an important concern because the resonant type of grating typically used in grating couplers produces non-negligible reflection even in the off-resonance mode of coupling. In the present invention, the minimization of reflection can be used to eliminate the need for an optical isolator between the grating and the laser source.

The grating coupler in the present invention can be made to benefit from any of these designs, or a combination thereof, depending on the particular grating embodiment. In addition, in the present invention, depending whether a spot-size converter is used in order to minimize the divergence of light incident on the grating coupler and depending on the effectiveness of such a spot-size converter, there may be an appreciable divergence of light in the lateral dimension. Consequently, the grating design in the lateral dimension may entail designing the grating to be two dimensional and collect and focus the laterally diverging light, which is typically not necessary for fiber grating couplers.

The present invention could be utilized to integrate a stack of planar waveguides that are coupled using the light coupling elements of this invention, namely gratings, turning mirror, and lenses. The stack of planar waveguides could be formed by bonding together more than two substrates, by growing/depositing multiple layers to form stacked waveguides, or by using a combination of both of these techniques.

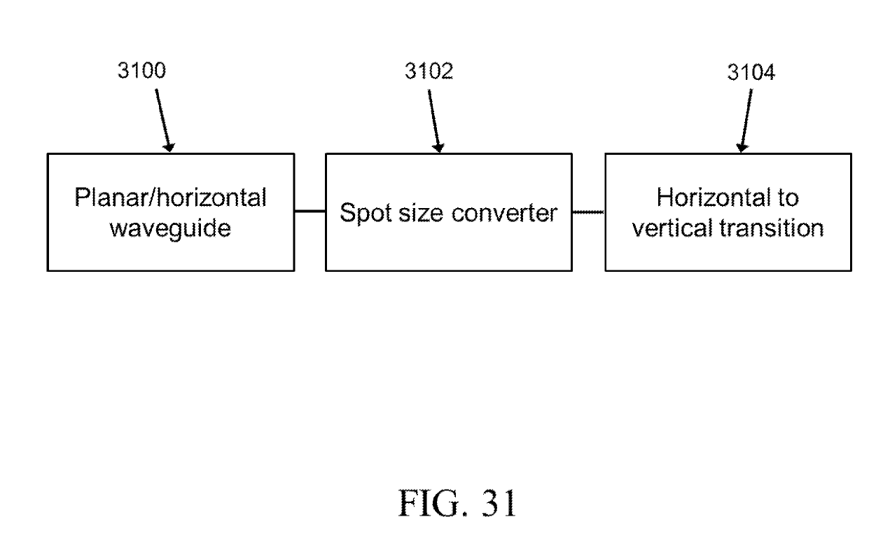

In the embodiment illustrated in FIG. 31, a surface emitting photonic device comprises a horizontal (with respect to the plane of the substrate) waveguide, a spot size converter, and a horizontal to out-of-plane (also sometimes referred to as vertical) transition element. The horizontal waveguide guides light in a plane of the substrate. The spot size converter alters the size, shape, and other properties, such as the divergence, of the light exiting or entering the waveguide. The horizontal to out-of-plane transition element redirects the planar guide light out of the plane of the substrate. The purpose of the spot size converter is to enable efficient coupling of light exiting or entering this surface emitting photonic device to or from other waveguides, devices, components, or photonic integrated circuits.

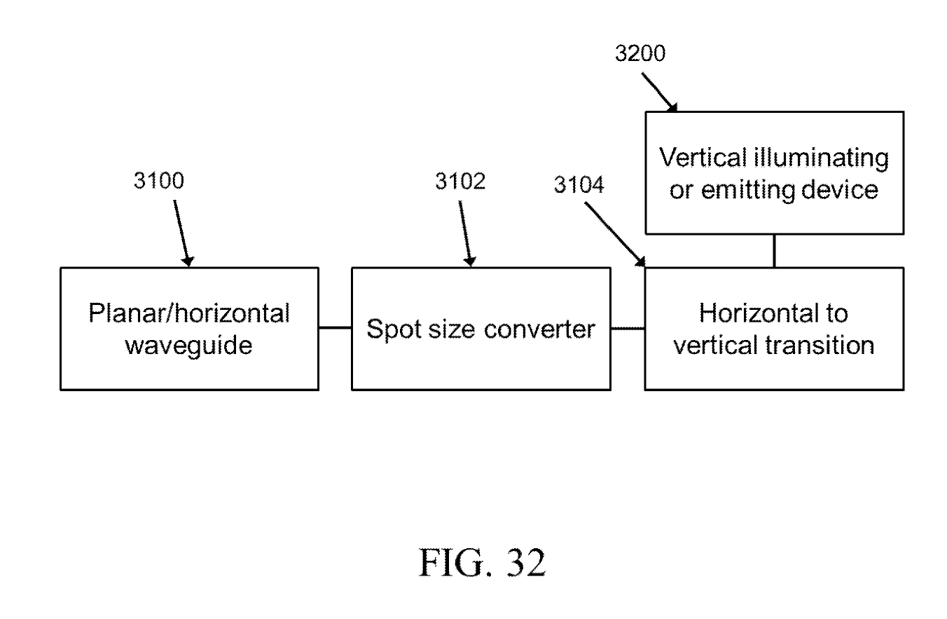

In the embodiment illustrated in FIG. 32, an out-of-plane illuminating or emitting device (such as, but not limited to, a vertical cavity surface emitting laser, a surface emitting photonic device as presented in FIG. 31, a surface illuminating photodetector, a vertical modulator, a vertical cavity semiconductor optical amplifier) is attached to another device comprising a horizontal to out-of-plane transition element, a spot size converter, and a horizontal (with respect to the plane of the substrate) waveguide. In this embodiment, a photonic integrated circuit can be formed by integrating more than one photonic device, or more than one photonic integrated circuit, in this fashion.

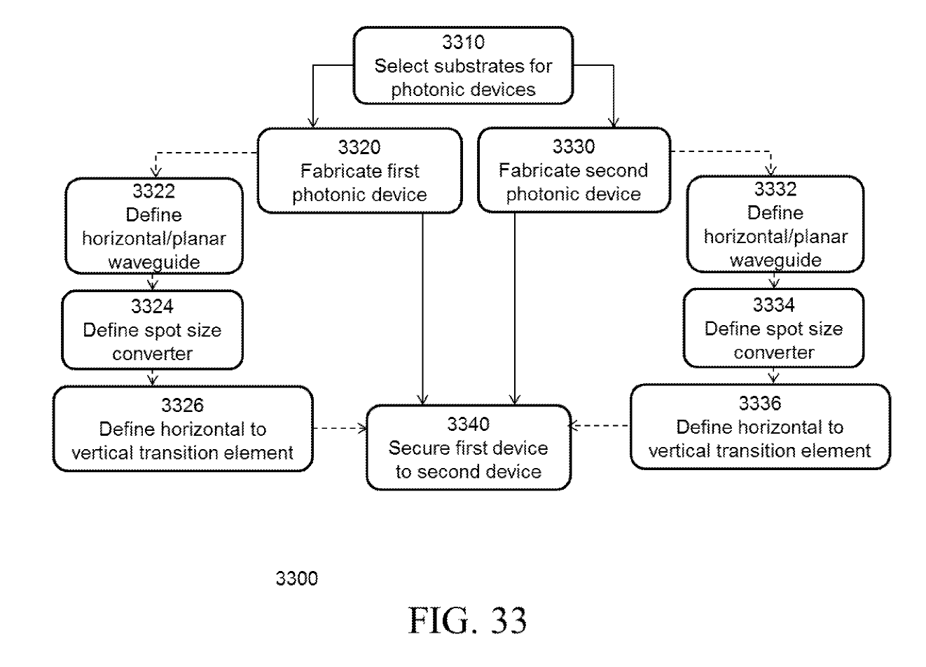

In the embodiment illustrated in FIG. 33, a flow is illustrated for forming a photonic integrated circuit from separate photonic devices. Firstly, substrates are selected for the photonic devices. Then the photonic devices are fabricated separately. The first photonic device may be fabricated in step 3320 as surface illuminating or emitting device (such as, but not limited to, a vertical cavity surface emitting laser, a surface illuminating photodetector, a vertical modulator, a vertical cavity semiconductor optical amplifier), or may be fabricated (with optional steps 3322, 3324, 3326) as a planar waveguide device comprising elements for vertical emission or illumination (such as, but not limited to a surface emitting photonic device as presented in FIG. 31). For the latter case, a horizontal/planar waveguide structure is formed, a spot size converter is formed, and a horizontal to out-of-plane transition element is formed. The sequence does not necessarily need to be carried out in this order, and some attributes of more than one of these elements may be formed with the same steps. Generally speaking, horizontal to out-of-plane, could also mean out-of-plane to horizontal, when referring to the direction of light propagation. A device may also operate in a bi-directional manner, where the same element, or combination of elements, propagates light in both directions.

1. A method, comprising:
selecting a first optical substrate and a second optical substrate, wherein at least the first substrate includes a planar waveguide;
selecting a beam direction transition that is optically coupled to the planar waveguide, the beam direction transition situated so as to define a beam propagation axis that includes a portion corresponding to an axis of the planar waveguide and a portion that extends from the beam direction transition through a major surface of a first optical substrate; and securing the second optical substrate to the first optical substrate so as to optically couple the beam propagation axis of the first optical substrate and the second optical substrate.

2. The method of claim 1, wherein the first and second optical substrates are secured by direct molecular bonding, adhesive bonding, bonding with an interfacial layer, flip-chip metal thermocompression bonding, or flip-chip solder bonding.

3. The method of claim 2, wherein the beam direction transition includes at least one of a grating coupler, an out-of-plane total internal reflection turning mirror, a lens, a prism, or a combination thereof.

4. The method of claim 3, wherein the second optical substrate includes a beam direction transition situated to optically couple the beam propagation axis into a planar waveguide in the second optical substrate.

5. The method of claim 4, wherein the beam direction transitions of the first and second optical substrates are monolithic to the first and second optical substrates, respectively.

6. The method of claim 3, further comprising at least one optical filter, optical coating, optical isolator, polarizer, or lens optically coupled to the beam propagation axis of the first substrate.

7. The method of claim 5, wherein the at least one optical filter, optical coating, optical isolator, polarizer, or lens optically coupled to the beam propagation axis of the first substrate is defined in the first optical substrate or the second optical substrate.

8. A photonic device, comprising:
at least one horizontal waveguide defined in a substrate;
at least one spot size converter defined in the substrate and optically coupled to the at least one horizontal waveguide, the spot size converter situated to receive an optical beam propagating in the horizontal waveguide or to direct an optical beam to the horizontal waveguide, the spot size convertor configured to produce a spot size converted optical beam based on a horizontal waveguide mode field diameter; and
at least one beam transition defined in the substrate and coupled to the at least one spot size converter and situated to receive or transmit the spot size converted optical beam.

9. The photonic device of claim 8, wherein the horizontal waveguide is at least one of a ridge, rib, strip, stripe, buried ridge, buried stripe, buried channel, photonic crystal, or slot waveguide.

10. The photonic device of claim 9, wherein said spot size converter transition element is selected from the group consisting of: a lateral down-tapered buried waveguide, a lateral up-tapered buried waveguide, a single lateral taper transition from a ridge waveguide to a grating coupler-matched waveguide, a multi-section taper transition from a ridge waveguide to a grating coupler-matched waveguide, a dual lateral overlapping buried waveguide taper, a dual lateral overlapping ridge waveguide taper, a nested taper transition from a ridge waveguide to a grating coupler-matched waveguide, a vertical down-tapered buried waveguide, a vertical down-tapered ridge waveguide, a vertical overlapping ridge waveguide taper, a vertical overlapping waveguide taper transition from a buried waveguide to a grating coupler-matched waveguide, a vertical overlapping waveguide taper transition from a ridge waveguide to a grating coupler-matched waveguide, a combined lateral and vertical ridge waveguide taper, a 2-D overlapping waveguide transition from a buried waveguide to a grating coupler-matched waveguide, and an overlapping waveguide taper transition with two sections from a ridge waveguide to a grating coupler-matched waveguide.

11. The photonic device of claim 10, wherein the spot size converter is situated to alter at least one of a beam size, beam shape, and beam divergence of a beam exiting or entering the optical waveguide as the beam propagates to or from the beam direction transition, and further wherein the beam direction transition alters a beam propagation direction from a horizontal direction to an out-of-plane direction.

12. The photonic device of claim 11, wherein the beam direction transition is selected from the group consisting of a total internal reflection mirror, turning mirror, curved total internal reflection mirror, grating, grating coupler, grating-assisted coupler, prism, or a combination of more than one of such elements.

13. The photonic device of claim 12, wherein the beam direction transition is situated so as to redirect a light path from horizontal to vertical with respect to the plane of the substrate.

14. A photonic circuit, comprising:
at least two photonic devices, wherein at least one of the photonic devices includes a planar waveguide, and the at least two or more photonic devices are secured to each other.

15. The photonic circuit of claim 13, wherein at least one of the photonic devices is a surface emitting photonic device.

16. The photonic circuit of claim 15, wherein at least one of the at least two photonic devices is said surface emitting device, comprising at least one horizontal waveguide and at least one spot size converter and at least one beam direction transition optically coupled to the spot size converter.

17. The photonic circuit of claim 15, wherein at least one of the photonic devices is optically coupled so as to receive an optical beam from the surface emitting device.

18. The photonic circuit of claim 15, wherein at least one of the at least two photonic devices includes a horizontal waveguide optically coupled to at least one spot size converter, and at least one beam direction transition optically coupled to the surface emitting device.

19. The photonic circuit of claim 15, wherein one of the at least two photonic devices is secured to a third photonic device so as to couple an optical beam between the first and third photonic devices.

20.-187. (canceled)
